(19) United States
(12) Patent Application Publication
(10) Pub. No.: US 2026/0172068 A1
(43) Pub. Date: Jun. 18, 2026

(54) MICRO-ACOUSTIC MULTIBAND FILTENNA

(71) Applicant: QUALCOMM Incorporated, San Diego, CA (US)

(72) Inventor: Edgar Konrad SCHMIDHAMMER, Stein an der Traun (DE)

(21) Appl. No.: 18/986,451

(22) Filed: Dec. 18, 2024

(51) Int. Cl. H04B 1/40; H01Q 5/335

(52) U.S. Cl. CPC H04B 1/40; H01Q 5/335

(57) ABSTRACT

Techniques and apparatus for processing a signal using an apparatus. One example apparatus includes an antenna circuit that generally includes (i) a radiating element configured to radiate electromagnetic waves and to have a first resonance frequency, (ii) at least one acoustic resonator electrically coupled to the radiating element and configured to have at least one second resonance frequency, (iii) a first filter branch electrically coupled to the radiating element and the at least one acoustic resonator and configured in combination with the radiating element and the at least one acoustic resonator to have a first operating frequency band, and (iv) a second filter branch electrically coupled to the radiating element and the at least one acoustic resonator and configured in combination with the radiating element and the at least one acoustic resonator to have a second operating frequency band different from the first operating frequency band.

### TECHNICAL FIELD

Certain aspects of the present disclosure generally relate to electronic components and, more particularly, to multiband filtennas with micro-acoustic resonators.

### BACKGROUND

Electronic devices include traditional computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast and so on. These systems may be capable of supporting communication with multiple users by sharing the available system resources (e.g., time, frequency, and power). Examples of such systems include code division multiple access (CDMA) systems, time division multiple access (TDMA) systems, frequency division multiple access (FDMA) systems, and orthogonal frequency division multiple access (OFDMA) systems, (e.g., a Long Term Evolution (LTE) system, or a New Radio (NR) system).

Wireless communication transceivers used in these electronic devices generally include multiple radio frequency (RF) filters for filtering a signal for a particular frequency or range of frequencies. Electroacoustic devices (e.g., “acoustic filters”) are used for filtering high-frequency (e.g., generally greater than 100 MHz) signals in many applications. Using a piezoelectric material as a vibrating medium, acoustic resonators operate by transforming an electrical signal wave that is propagating along an electrical conductor into an acoustic wave that is propagating via the piezoelectric material. The acoustic wave propagates at a velocity having a magnitude that is significantly less than that of the propagation velocity of the electromagnetic wave. Generally, the magnitude of the propagation velocity of a wave is proportional to a size of a wavelength of the wave. Consequently, after conversion of an electrical signal into an acoustic signal, the wavelength of the acoustic signal wave is significantly smaller than the wavelength of the electrical signal wave. The resulting smaller wavelength of the acoustic signal enables filtering to be performed using a smaller filter device. This permits acoustic resonators to be used in electronic devices having size constraints, such as the electronic devices enumerated above (e.g., particularly including portable electronic devices, such as smartphones).

Today, surface acoustic wave (SAW) or bulk acoustic wave (BAW) components may be used in wireless communication devices, such as for implementing RF filters. In SAW technology, the acoustic wave propagates laterally on a surface of a piezoelectric substrate, with the movement of the piezoelectric material generated by metal interdigital transducers (IDTs) on the surface. The wavelength of the acoustic wave may be defined by the pitch (e.g., the width of the metal finger and gap) of the IDT. In BAW technology, the acoustic wave propagates vertically through a three-dimensional structure, with an electric field applied through electrodes above and below a piezoelectric material. The wavelength, in this case, is approximately defined by the thickness of the piezoelectric material.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages described herein.

Certain aspects of the present disclose provide an apparatus. The apparatus includes an antenna circuit that generally includes (i) a radiating element configured to radiate electromagnetic waves and to have a first resonance frequency, (ii) at least one acoustic resonator electrically coupled to the radiating element and configured to have at least one second resonance frequency, (iii) a first filter branch electrically coupled to the radiating element and the at least one acoustic resonator and configured in combination with the radiating element and the at least one acoustic resonator to have a first operating frequency band, and (iv) a second filter branch electrically coupled to the radiating element and the at least one acoustic resonator and configured in combination with the radiating element and the at least one acoustic resonator to have a second operating frequency band different from the first operating frequency band. The antenna circuit may be configured to have a filter transfer function based at least in part on the first resonance frequency and the second resonance frequency.

Certain aspects of the present disclosure are directed to a method of processing a signal using an antenna circuit. The method generally includes: (i) filtering the signal with a radiating element included in the antenna circuit, the radiating element being configured to radiate electromagnetic waves and to have a first resonance frequency, (ii) filtering the signal with at least one acoustic resonator included in the antenna circuit and electrically coupled to the radiating element, the at least one acoustic resonator being configured to have at least one second resonance frequency, (iii) filtering the signal with a first filter branch electrically coupled to the radiating element and the at least one acoustic resonator, the first filter branch being configured in combination with the radiating element and the at least one acoustic resonator to have a first operating frequency band, and (iv) filtering the signal with a second filter branch electrically coupled to the radiating element and the at least one acoustic resonator, the second filter branch being configured in combination with the radiating element and the at least one acoustic resonator to have a second operating frequency band different from the first operating frequency band. The antenna circuit may be configured to have a filter transfer function based at least in part on the first resonance frequency and the second resonance frequency.

Certain aspects of the present disclosure are directed to a packaged assembly comprising a filtenna, as described herein.

Certain aspects of the present disclosure are directed to a wireless device. The wireless device generally includes a filtenna, as described herein, and a radio frequency (RF) circuit coupled to the filtenna.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1A is a diagram of a perspective view of an example electroacoustic device, in which certain aspects of the present disclosure may be practiced.

FIG. 1B is a diagram of a cross-sectional view of the example electroacoustic device of FIG. 1A.

FIG. 1C is a cross-sectional view of another example electroacoustic device, in which certain aspects of the present disclosure may be practiced.

FIG. 2A is a top view of an example electrode structure of an electroacoustic device, in which certain aspects of the present disclosure may be practiced.

FIG. 2B is a top view of another example electrode structure of an electroacoustic device, in which certain aspects of the present disclosure may be practiced.

FIG. 3A is a diagram of a perspective view of an example electroacoustic device, in which certain aspects of the present disclosure may be practiced.

FIG. 3B is a diagram of a cross-sectional view of the example electroacoustic device of FIG. 3A.

FIG. 4A is a diagram of an antenna and a filter circuit, separated by a transmission line.

FIG. 4B is a diagram of an example filtenna, in accordance with certain aspects of the present disclosure.

FIG. 5A is a circuit diagram of a filtenna where the antenna operates at its series resonance, in accordance with certain aspects of the present disclosure.

FIG. 5B is a circuit diagram of a filtenna where the antenna operates at its parallel resonance, in accordance with certain aspects of the present disclosure.

FIGS. 6A, 6B, and 6C are cross-sectional views of example modules including a filtenna, in accordance with certain aspects of the present disclosure.

FIG. 7 is a block diagram depicting an example dual-polarized filtenna sub-array for phased array applications, in accordance with certain aspects of the present disclosure.

FIG. 8 is a frequency spectrum illustrating a distribution of example frequency responses and resonance frequencies associated with filtenna, in accordance with certain aspects of the present disclosure.

FIGS. 9A and 9B are block diagrams of a single-band filtenna and a dual-band filtenna, respectively, illustrating resonant and non-resonant nodes, in accordance with certain aspects of the present disclosure.

FIGS. 10A, 11A, and 12A are block diagrams depicting example dual-band filtennas, in accordance with certain aspects of the present disclosure.

FIGS. 10B, 11B, and 12B are schematic diagrams of the example dual-band filtennas of FIGS. 10A, 11A, and 12A, respectively, in accordance with certain aspects of the present disclosure.

FIGS. 10C, 11C, 11D, and 12C are top views of example acoustic chip layouts for the example dual-band filtennas of FIGS. 10A, 11A, 11A, and 12A, respectively, in accordance with certain aspects of the present disclosure.

FIG. 10D is a frequency spectrum illustrating a distribution of example frequency responses and resonance frequencies associated with a dual-band filtenna, in accordance with certain aspects of the present disclosure.

FIG. 13A is a block diagram depicting an example tri-band filtenna, in accordance with certain aspects of the present disclosure.

FIG. 13B is a schematic diagram of the example tri-band filtenna of FIG. 13A, in accordance with certain aspects of the present disclosure.

FIG. 13C is a top view of an example acoustic chip layout for the example tri-band band filtenna of FIG. 13A, in accordance with certain aspects of the present disclosure.

FIG. 13D is a frequency spectrum illustrating a distribution of example frequency responses and resonance frequencies associated with a tri-band filtenna, in accordance with certain aspects of the present disclosure.

FIG. 13E is a cross-sectional view of an example module including a tri-band filtenna, in accordance with certain aspects of the present disclosure.

FIG. 14 is a flow diagram of example operations for processing a signal using a filtenna, in accordance with certain aspects of the present disclosure.

FIG. 15 illustrates a schematic diagram and implementation of an example filtenna circuit, in accordance with certain aspects of the present disclosure.

FIG. 16 is a functional block diagram of at least a portion of an example simplified wireless transceiver circuit in which a filtenna may be employed.

FIG. 17 is a diagram of an environment that includes an electronic device having a wireless transceiver such as the transceiver circuit of FIG. 16.

To facilitate understanding, identical reference numerals have been used, where possible, to designate identical elements that are common to the figures. It is contemplated that elements disclosed in one aspect may be beneficially utilized in other aspects without specific recitation.

### DETAILED DESCRIPTION

Certain aspects of the present disclosure generally relate to a multiband filtenna implemented with micro-acoustic resonators. As used herein, the term “filtenna” is a combination of the words “filter” and “antenna” and describes the combination of one or more filters and an antenna into one common device. The multiband filtenna may include a plurality of filter branches. The plurality of filter branches (each including one or more micro-acoustic resonators) and the antenna of the multiband filtenna (including a radiating element) may both be coupled to at least one micro-acoustic resonator at a common node. Each of the plurality of filter branches is configured in combination with the antenna and the at least one acoustic resonator to have a different operating frequency band. In some cases, the multiband filtenna may be referred to as an “integrated antenna,” an “antenna circuit,” or simply as an “antenna” (with a radiating element and one or more acoustic resonators). In some aspects, the radiating element or structure has a resonance that in combination with the micro-acoustic resonators provides a filter transfer function (e.g., the radiating element forms one resonator of the network of resonators that together define the filter transfer function (e.g., passband, stopband, and the like)).

The detailed description set forth below in connection with the appended drawings is intended as a description of exemplary implementations and is not intended to represent the only implementations in which aspects of the present disclosure may be practiced. The term “exemplary” used throughout this description means “serving as an example, instance, or illustration,” and should not necessarily be construed as preferred or advantageous over other exemplary implementations. The detailed description includes specific details for the purpose of providing a thorough understanding of the exemplary implementations. In some instances, some devices are shown in block diagram form. Drawing elements that are common among the following figures may be identified using the same reference numerals.

### Example Electroacoustic Devices

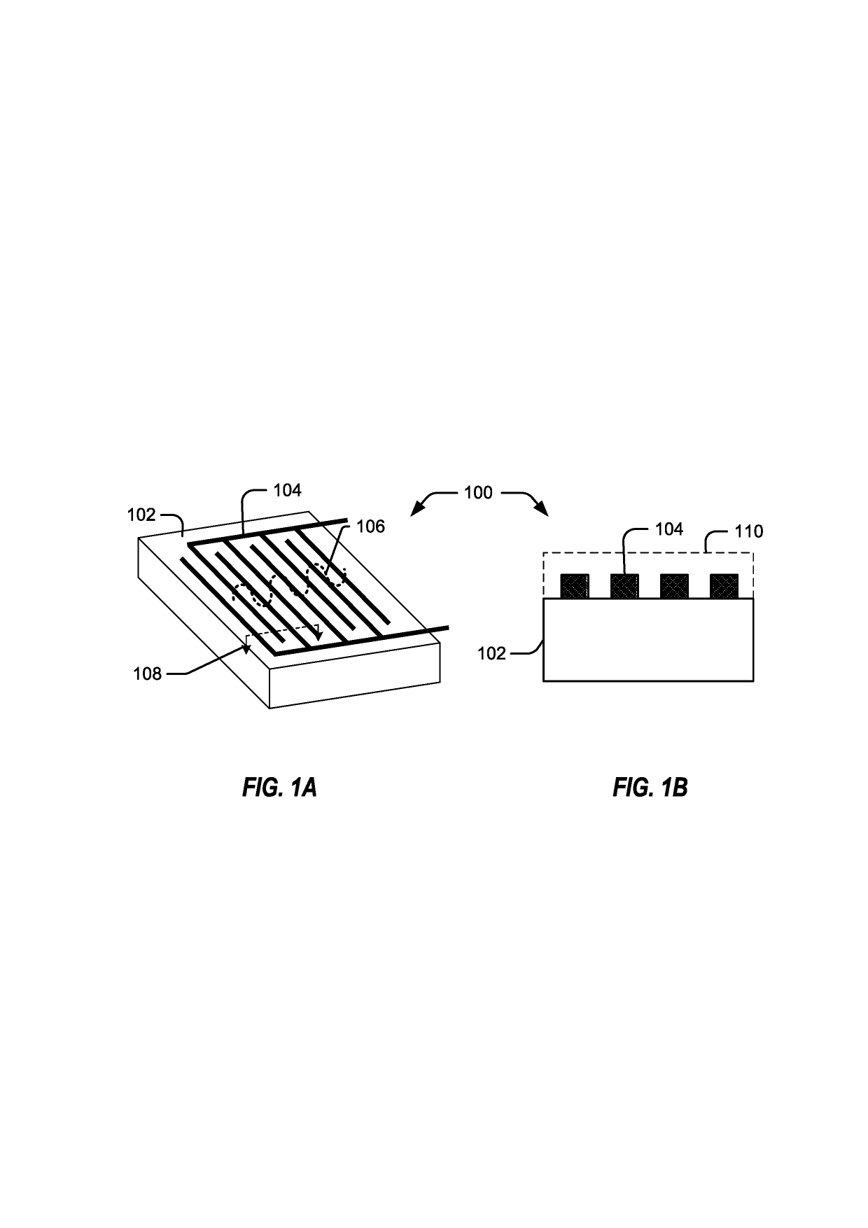

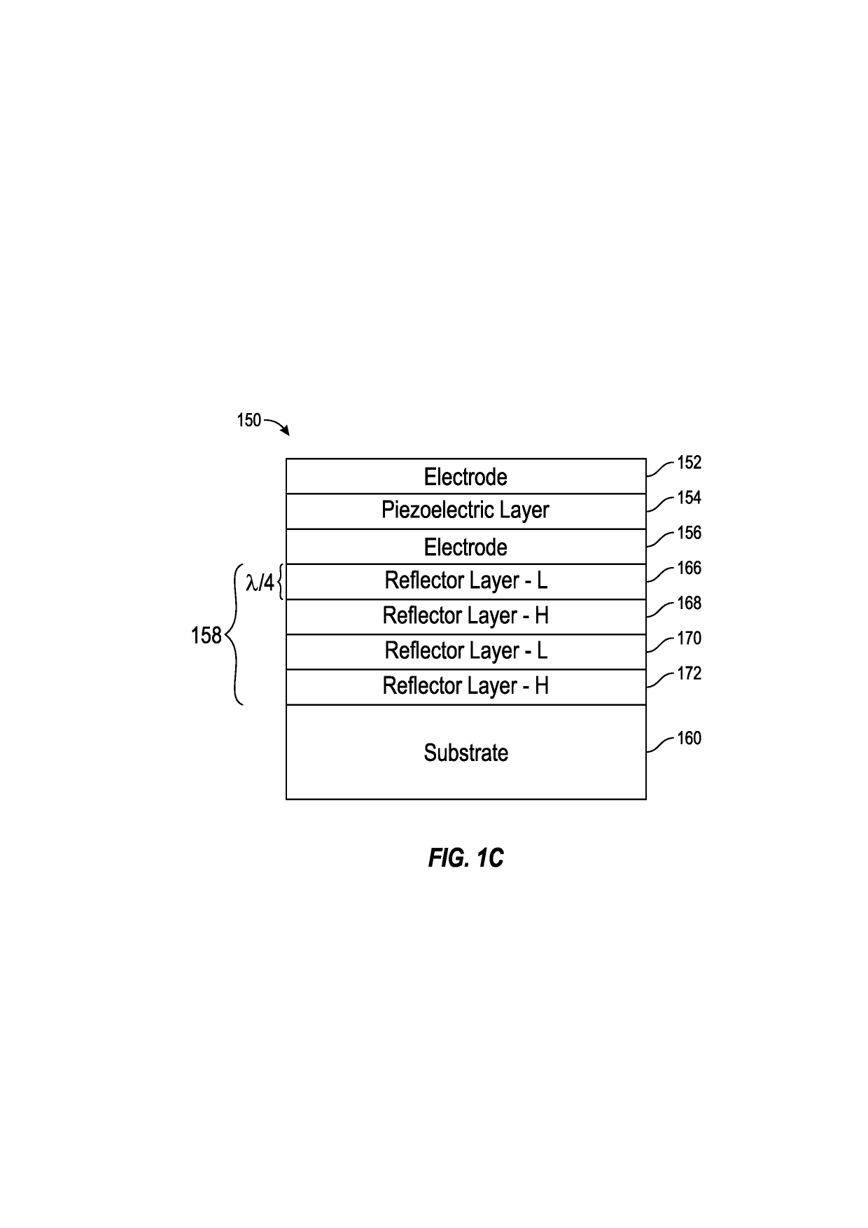

As noted above, the filtenna includes multiple micro-acoustic resonators. FIGS. 1A-3B provide examples of aspects of the micro-acoustic resonators that may be used for the filtennas described herein, although other micro-acoustic stacks and configurations are possible.

FIG. 1A is a diagram of a perspective view of an example electroacoustic device 100. The electroacoustic device 100 may be configured as or may be a portion of a SAW resonator. In certain descriptions herein, the electroacoustic device 100 itself may be referred to as a SAW resonator. However, while the following description focuses on SAW resonators, the reader is to understand that other electroacoustic device types (e.g., bulk acoustic wave (BAW) resonators (including thin-film bulk acoustic resonators (FBARs) and solidly mounted resonators (SMRs)), micro-electromechanical systems (MEMS) devices, and the like) may be used in place of or in conjunction with SAW resonators.

The electroacoustic device 100 includes an electrode structure 104, that may be referred to as an interdigital transducer (IDT), on the surface of a piezoelectric material 102. The electrode structure 104 generally includes first and second comb-shaped electrode structures (electrically conductive and generally metallic) with electrode fingers extending from two busbars towards each other arranged in an interlocking manner in between the two busbars (e.g., arranged in an interdigitated manner, as shown). An electrical signal excited in the electrode structure 104 (e.g., applying an AC voltage) is transformed into an acoustic wave 106 that propagates in a particular direction via the piezoelectric material 102. The acoustic wave 106 is transformed back into an electrical signal and provided as an output. In many applications, the piezoelectric material 102 has a particular crystal orientation such that when the electrode structure 104 is arranged relative to the crystal orientation of the piezoelectric material 102, the acoustic wave mainly propagates in a direction perpendicular to the direction of the fingers (e.g., parallel to the busbars).

FIG. 1B is a diagram of a cross-sectional view of the electroacoustic device 100 of FIG. 1A along a cross-section 108 shown in FIG. 1A. The electroacoustic device 100 is illustrated by a simplified layer stack including the piezoelectric material 102 with the electrode structure 104 disposed on the piezoelectric material 102. The electrode structure 104 is electrically conductive and generally formed from metallic materials. The electrode structure 104 may alternatively be formed from materials that are electrically conductive, but non-metallic (e.g., graphene). The piezoelectric material 102 may be formed from a variety of materials such as quartz, lithium tantalate (LiTaO₃), lithium niobite (LiNbO₃), doped variants of these, other piezoelectric materials, or other crystals. The piezoelectric material 102 may be referred to as a “piezoelectric substrate,” but may also be referred to as a “piezoelectric layer,” such as in examples where there are additional layers below the piezoelectric material 102.

It should be appreciated that more complicated layer stacks including layers of various materials may be possible within the stack. For example, optionally, a temperature compensation layer 110 denoted by the dashed lines may be disposed above the electrode structure 104. The piezoelectric material 102 may be extended with multiple interconnected electrode structures disposed thereon to form a multi-resonator filter or to provide multiple filters. While not illustrated, when provided as an integrated circuit component, a cap layer may be provided over the electrode structure 104. The cap layer is applied so that a cavity is formed between the electrode structure 104 and an under surface of the cap layer. Electrical vias or bumps that allow the component to be electrically connected to connections on a substrate (e.g., via flip-chip or other techniques) may also be included.

FIG. 1C is a cross-sectional view of an electroacoustic device 150. The electroacoustic device 150 may be configured as or be a portion of a BAW resonator, such as an SMR-type BAW. As shown, the electroacoustic device 150 includes a top electrode 152, a piezoelectric layer 154, a bottom electrode 156, a Bragg reflector 158, and a substrate 160.

As shown, the top electrode 152 is disposed above the piezoelectric layer 154. The top electrode 152 may include an electrically conductive material such as a metal or metal alloy including aluminum (Al), chromium (Cr), cobalt (Co), copper (Cu), gold (Au), molybdenum (Mo), platinum (Pt), ruthenium (Ru), tantalum (Ta), titanium (Ti), tungsten (W), a combination thereof (e.g., AlCu), or any other suitable material. In certain cases, the conductive material may include graphene or other electrically conductive, non-metallic materials. The piezoelectric layer 154 may include a piezoelectric material, such as aluminum nitride (AlN), aluminum scandium nitride (AlScN), zinc oxide (ZnO), a quartz crystal (such as lithium tantalate (LiTaO₃) or lithium niobite (LiNbO₃)), doped variants of these, or other suitable piezoelectric materials.

The bottom electrode 156 may include an electrically conductive material such as a metal or metal alloy, for example, as described herein with respect to the top electrode 152. In certain aspects, the bottom electrode 156 may have the same form, size, and/or structure as the top electrode 152. For example, the electrodes 152, 156 may both be electrode plates. In certain cases, the bottom electrode 156 may have a different form, size, and/or structure from the top electrode 152.

The Bragg reflector 158 may acoustically isolate the BAW resonator from the substrate 160 or at least reduce the acoustic coupling between the BAW resonator and the substrate 160. In general, the Bragg reflector 158 may include alternating layers of materials having low acoustic impedance and materials having high acoustic impedance, as further described herein with respect to FIG. 1C.

The substrate 160 may be disposed below the Bragg reflector 158, such that the substrate 160 is arranged under the top electrode 152 and the bottom electrode 156. The substrate 160 may serve as a carrier for the BAW resonator. In some aspects, the substrate 160 may be formed from a semiconductor wafer, such as a silicon (Si) wafer. The substrate 160 may comprise any of various other suitable materials, such as alumina (Al₂O₃), glass, or sapphire.

When an electrical signal (e.g., an AC voltage signal) is applied to the electrodes 152 and 156, the electrical signal is transformed into an acoustic wave that propagates in the piezoelectric layer 154. That is, applying an electrical signal to the piezoelectric layer 154 between the electrodes 152 and 156 transduces the electrical signal to the acoustic wave in the piezoelectric layer 154. At certain frequencies, a resonant and/or anti-resonant mechanical standing wave may be formed, thus enabling the filter functionality. As noted above, to avoid leakage into the substrate 160, the Bragg reflector 158 may be disposed below the bottom electrode 156. The Bragg reflector 158 may have high acoustic reflectivity and may reflect an acoustic wave back towards the piezoelectric layer 154 and the top electrode 152. Reflecting the acoustic waves may enhance the efficiency of the BAW resonator and acoustically decouple the substrate 160 from the BAW resonator. In many applications, the piezoelectric layer 154 has a particular crystal orientation such that when the top electrode 152 is arranged relative to the crystal orientation of the piezoelectric layer 154, the acoustic wave mainly propagates in a direction from the top electrode 152 to the bottom electrode 156.

FIG. 1C also illustrates example reflector layers of the Bragg reflector 158 in the electroacoustic device 150. In this example, the Bragg reflector 158 includes a reflector layer 166, a reflector layer 168, a reflector layer 170, and a reflector layer 172. In certain cases, the Bragg reflector 158 may have any suitable number of reflector layers, such as fewer or more than four reflector layers as depicted in this example. The reflector layer 168 and reflector layer 172 may include a material having an acoustic impedance that is higher (as indicated by the “Reflector Layer - H” label) than the acoustic impedance of a material of the reflector layer 166 and reflector layer 170 (as indicated by the “Reflector Layer - L” label). For example, the reflector layer 166 and reflector layer 170 may include silicon dioxide (SiO₂) or aluminum nitride (AlN), whereas the reflector layer 168 and reflector layer 172 may include tungsten (W) or another suitable material with a higher acoustic impedance than silicon dioxide or aluminum nitride.

The reflector layers 166, 168, 170, 172 may have the same thickness (e.g., a quarter wavelength (λ/4) in thickness according to the operating frequency range of the electroacoustic device 150) or vary in thickness. While in this example, the reflector layers 166, 168, 170, 172 are depicted as having the same thickness, the reflector layers 166, 168, 170, 172 may vary in thickness (i.e., individual layers may have different thicknesses).

Although FIG. 1C is depicted as an SMR-type BAW resonator, it is to be understood that certain aspects of the present disclosure may alternatively be implemented with other types of BAW resonators, such as thin-film bulk acoustic resonators (FBARs).

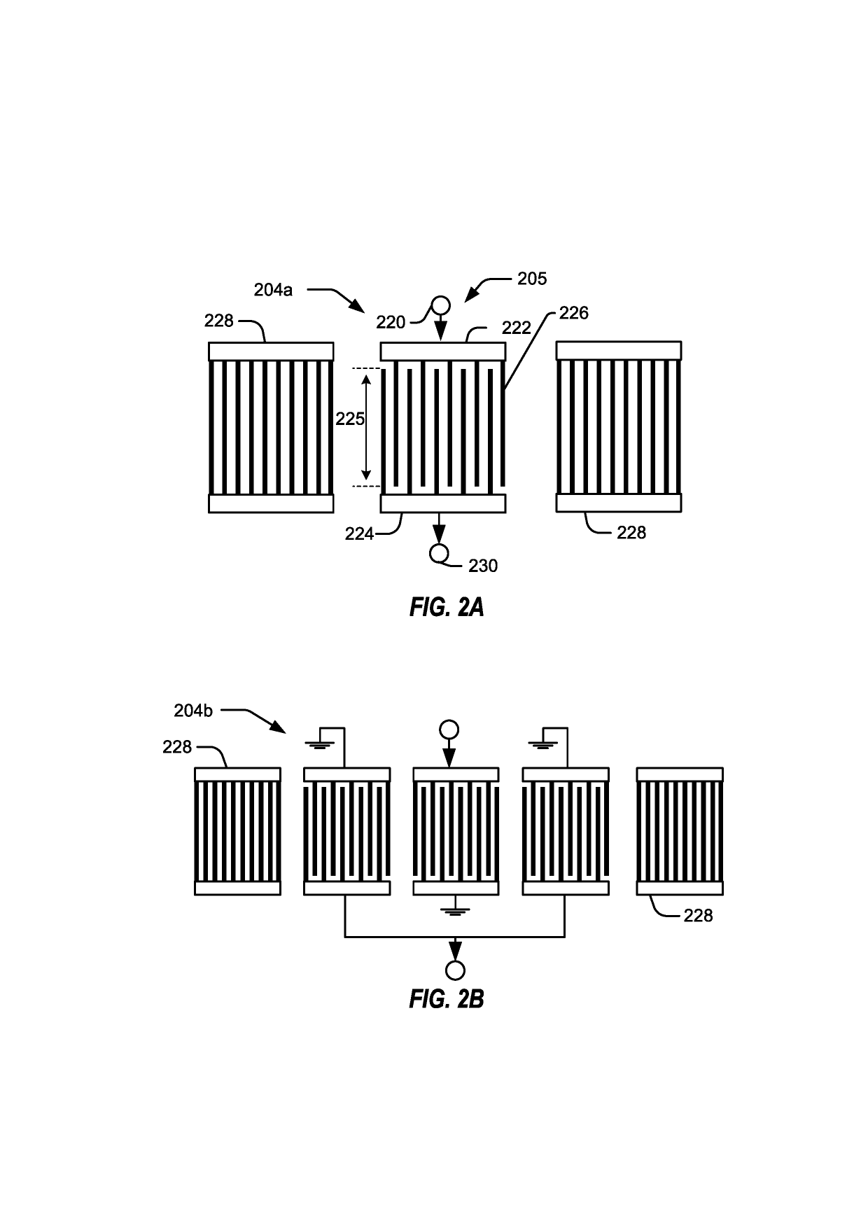

FIG. 2A is a top view of an example electrode structure 204a of an electroacoustic device. The electrode structure 204a has an IDT 205 that includes a first busbar 222 (e.g., first conductive segment or rail) electrically coupled to a first terminal 220 and a second busbar 224 (e.g., second conductive segment or rail) spaced from the first busbar 222 and coupled to a second terminal 230. A plurality of conductive fingers 226 are connected to either the first busbar 222 or the second busbar 224 in an interdigitated manner. Fingers 226 connected to the first busbar 222 extend towards the second busbar 224 but do not connect to the second busbar 224 so that there is a small gap between the ends of these fingers 226 and the second busbar 224. Likewise, fingers 226 connected to the second busbar 224 extend towards the first busbar 222 but do not connect to the first busbar 222 so that there is a small gap between the ends of these fingers 226 and the first busbar 222. Similarly, small gaps may also be formed between fingers 226 and any structure extending from the first busbar 222 or the second busbar 224 (e.g., stub fingers).

Between the busbars, there is an overlap region including a central region where a portion of one finger overlaps with a portion of an adjacent finger as illustrated by the central region 225. This central region 225 including the overlap may be referred to as the aperture, track, or active region where electric fields are produced between the fingers 226 to cause an acoustic wave to propagate in this region of the piezoelectric material 102. The periodicity of the fingers 226 is referred to as the pitch of the IDT. The pitch may be indicated in various ways. For example, in certain aspects, the pitch may correspond to a magnitude of a distance between fingers in the central region 225. This distance may be defined, for example, as the distance between center points of each of the fingers (and may be generally measured between a right (or left) edge of one finger and the right (or left) edge of an adjacent finger when the fingers have uniform width). In certain aspects, an average of distances between adjacent fingers may be used as the pitch. The frequency at which the piezoelectric material vibrates is a main resonance frequency of the electrode structure 204a. This frequency is determined at least in part by the pitch of the IDT 205 and other properties of the electroacoustic device 100.

The IDT 205 is arranged between two reflectors 228 which reflect the acoustic wave back towards the IDT 205 for the conversion of the acoustic wave into an electrical signal via the IDT 205 in the configuration shown and to prevent losses (e.g., confine and prevent escaping acoustic waves). Each reflector 228 has two busbars and a grating structure of conductive fingers that each connect to both busbars. The pitch of the reflector may be similar to or the same as the pitch of the IDT 205 to reflect acoustic waves in the resonant frequency range. But many configurations are possible.

When converted back to an electrical signal, the converted electrical signal may be provided as an output, such as to one of the first terminal 220 or the second terminal 230, while the other terminal may function as an input.

A variety of electrode structures are possible. FIG. 2A may generally illustrate a one-port configuration. Other configurations (e.g., two-port configurations) are also possible. For example, the electrode structure 204a may have an input IDT 205 where each terminal 220 and 230 functions as an input. In this event, an adjacent output IDT (not illustrated) that is positioned between the reflectors 228 and adjacent to the input IDT 205 may be provided to convert the acoustic wave propagating in the piezoelectric material 102 to an electrical signal to be provided at output terminals of the output IDT.

FIG. 2B is a top view of another example electrode structure 204b of an electroacoustic device. In this case, a dual-mode SAW (DMS) electrode structure 204b is illustrated, the DMS structure being a structure that may induce multiple resonances. The electrode structure 204b includes multiple IDTs arranged between reflectors 228 and connected as illustrated. The electrode structure 204b is provided to illustrate the variety of electrode structures in which principles described herein may be applied.

It should be appreciated that while a certain number of fingers 226 are illustrated, the number of actual fingers and length(s) and width(s) of the fingers 226 and busbars may be different in an actual implementation. Such parameters depend on the particular application and desired filter characteristics. In addition, a SAW filter may include multiple interconnected electrode structures each including multiple IDTs to achieve a desired passband (e.g., multiple interconnected resonators or IDTs to form a desired filter transfer function).

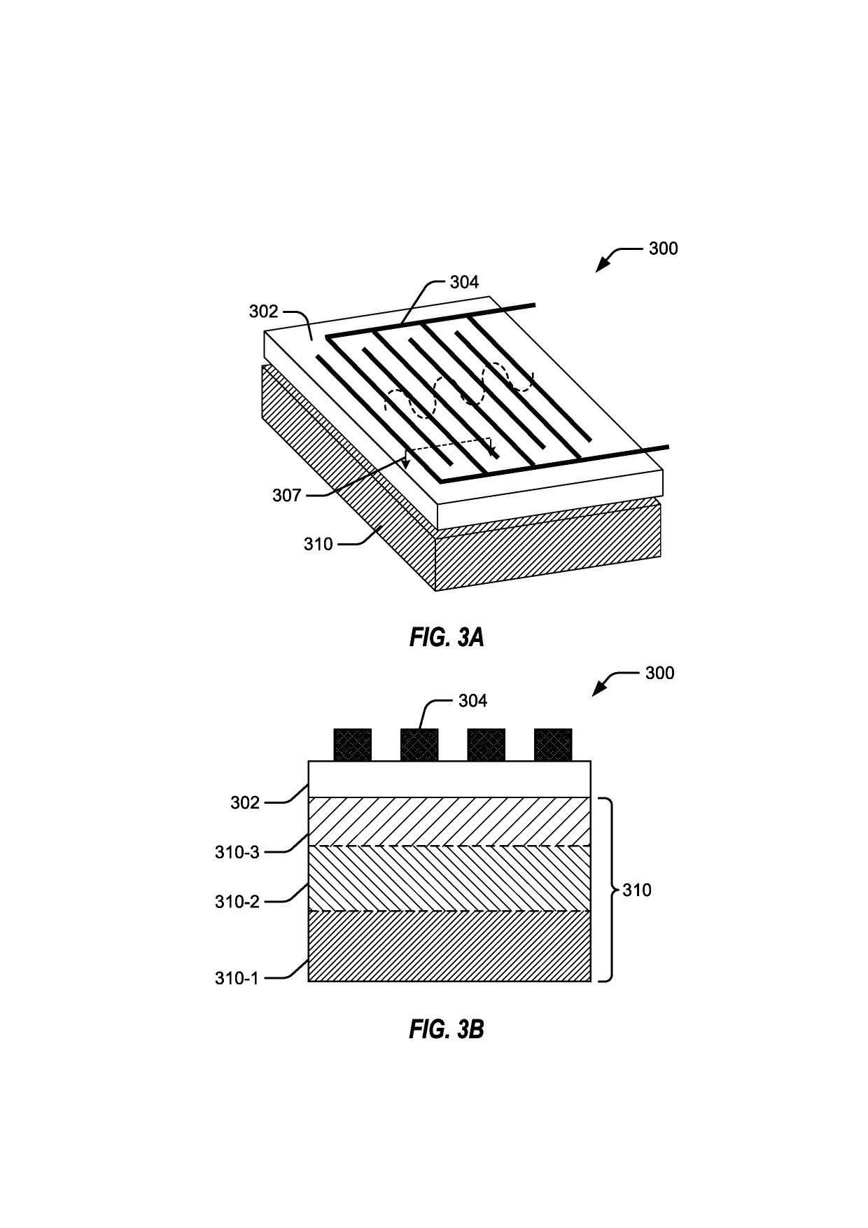

FIG. 3A is a diagram of a perspective view of another example of an electroacoustic device 300. The electroacoustic device 300 (e.g., that may be configured as or be a part of a SAW resonator) is similar to the electroacoustic device 100 of FIG. 1A but has a different layer stack. In particular, the electroacoustic device 300 includes a thin piezoelectric material 302 that is provided on a substrate 310 (e.g., silicon). The electroacoustic device 300 may be referred to as a thin-film SAW resonator (TF-SAW) in some cases. Based on the type of piezoelectric material 302 used (e.g., typically having higher coupling factors relative to the electroacoustic device 100 of FIG. 1A) and a controlled thickness of the piezoelectric material 302, the particular acoustic wave modes excited may be slightly different than those in the electroacoustic device 100 of FIG. 1A. Based on the design (thicknesses of the layers, and selection of materials, etc.), the electroacoustic device 300 may have a higher quality factor (Q) as compared to the electroacoustic device 100 of FIG. 1A. In general, the substrate 310 may be substantially thicker than the piezoelectric material 302 (e.g., on the order of 50 to 100 times thicker, or more). The substrate 310 may include other layers (or other layers may be included between the substrate 310 and the piezoelectric material 302).

FIG. 3B is a diagram of a cross-sectional view of the electroacoustic device 300 of FIG. 3A showing an exemplary layer stack (along a cross-section 307). In the example shown in FIG. 3B, the substrate 310 may include sublayers such as a substrate sublayer 310-1 (e.g., of silicon) that may have a higher resistance (e.g., relative to the other layers – a high resistivity layer). The substrate 310 may further include a trap rich layer 310-2 (e.g., polysilicon). The substrate 310 may further include a compensation layer 310-3 (e.g., silicon dioxide (SiO₂) or another dielectric material) that may provide temperature compensation and other properties. These sublayers may be considered part of the substrate 310 or their own separate layers. A relatively thin piezoelectric material 302 is provided on the substrate 310 with a particular thickness for providing a particular acoustic wave mode (e.g., as compared to the electroacoustic device 100 of FIG. 1A where the thickness of the piezoelectric material 102 may not be a significant design parameter beyond a certain thickness and may be generally thicker as compared to the piezoelectric material 302 of the electroacoustic device 300 of FIGS. 3A and 3B). The electrode structure 304 is positioned above the piezoelectric material 302. In addition, in some aspects, there may be one or more layers (not shown) possible above the electrode structure 304 (e.g., such as a thin passivation layer).

Based on the type of piezoelectric material, the thickness, and the overall layer stack, the coupling to the electrode structure 304 and acoustic velocities within the piezoelectric material in different regions of the electrode structure 304 may differ between different types of electroacoustic devices, such as between the electroacoustic device 100 of FIG. 1A and the electroacoustic device 300 of FIGS. 3A and 3B.

### Example Single-Band Filtenna with Micro-Acoustic Resonators

Traditionally, the filtering portion of a radio frequency front-end (RFFE) is accomplished with one or more filters coupled to a device’s antenna, which may be matched to the characteristic impedance of the RFFE. However, depending on the desired size of the matched antenna and the specifications of the filter(s), connecting the filter(s) directly to the matched antenna may not be feasible. As a result, an additional transmission line is typically used to connect the matched antenna with the filter(s), adding additional loss in the signal chain. The antennas considered in such systems are typically matched to the system characteristic impedance Z₀ (e.g., Z₀ = 50 Ω), as are the filters.

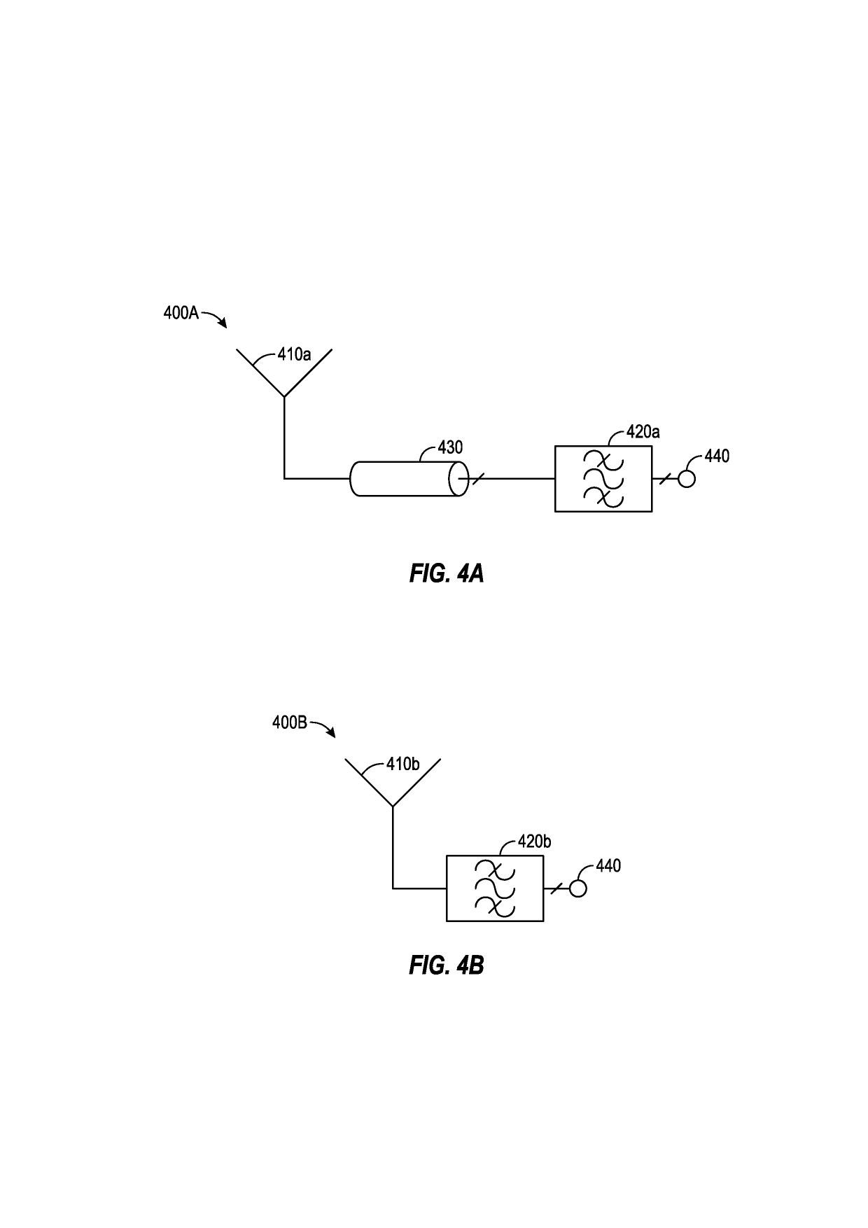

FIG. 4A is a diagram 400A of an antenna 410a and a filter circuit 420a, coupled by and separated by a transmission line 430. The filter circuit 420a may be coupled to a port 440. In this case, the antenna 410a may be designed separately from the filter circuit 420a and may have a frequency behavior that is independent from the filter circuit 420a. The antenna 410a and/or the filter circuit 420a may be designed to match a characteristic impedance (e.g., 50 Ω) of a radio frequency (RF) transmitter or receiver.

According to certain aspects of the present disclosure, the antenna and the filter circuit can be combined in what is referred to herein as a “filtenna,” where the antenna is an integral part of the filter. FIG. 4B is a diagram of an example filtenna 400B including an antenna 410b and a filter circuit 420b, in accordance with certain aspects of the present disclosure.

The combination of the filter circuit into the antenna design in a filtenna has some advantages. By utilizing the antenna 410b as one resonator being part of the overall filtenna filter (e.g., including a network of other resonators such as micro-acoustic resonators), the transmission line losses and matching losses present in some approaches may be minimized, or at least significantly reduced. Note, that in this case, the antenna 410b need not be matched to a characteristic impedance. In some aspects, the filtenna 400B may be realized in a module (e.g., a packaged assembly) using acoustic resonators along with a radiating element (e.g., an antenna element such as a patch, dipole, and the like). The acoustic resonators may be implemented by any of various suitable devices, such as BAW resonators (including FBARs and SMRs), SAW resonators, MEMS devices, or any combination thereof. The antenna portion of the filtenna 400B may be designed to operate based on the wave speed of light (e.g., electromagnetic oscillations), whereas the acoustic resonators may be designed to operate based on a different wave speed, the speed of sound (e.g., acoustic oscillations) in a solid body.

The filtenna concept is different from some approaches in the sense that the filter circuit 420b and the antenna 410b in the filtenna 400B are co-designed. Furthermore, the impedance of the filtenna 400B can be anything, as this may only be dictated by the filtering specifications and the theoretical boundaries as given by filter theory (e.g., coupling matrix designs). An advantage of the filtenna 400B may be a significant reduction of ohmic losses, which may not only increase the signal fidelity, but may also improve the overall system performance (less power consumption, less generated heat, etc.). In addition, highly compact filtenna designs are achievable, as the antenna 410b and the filter circuit 420b can be integrated into a very compact module. In certain aspects, the antenna 410b used in the filtenna 400B may have a quality factor (Q) higher than 10, and/or a radiation efficiency greater than 80%.

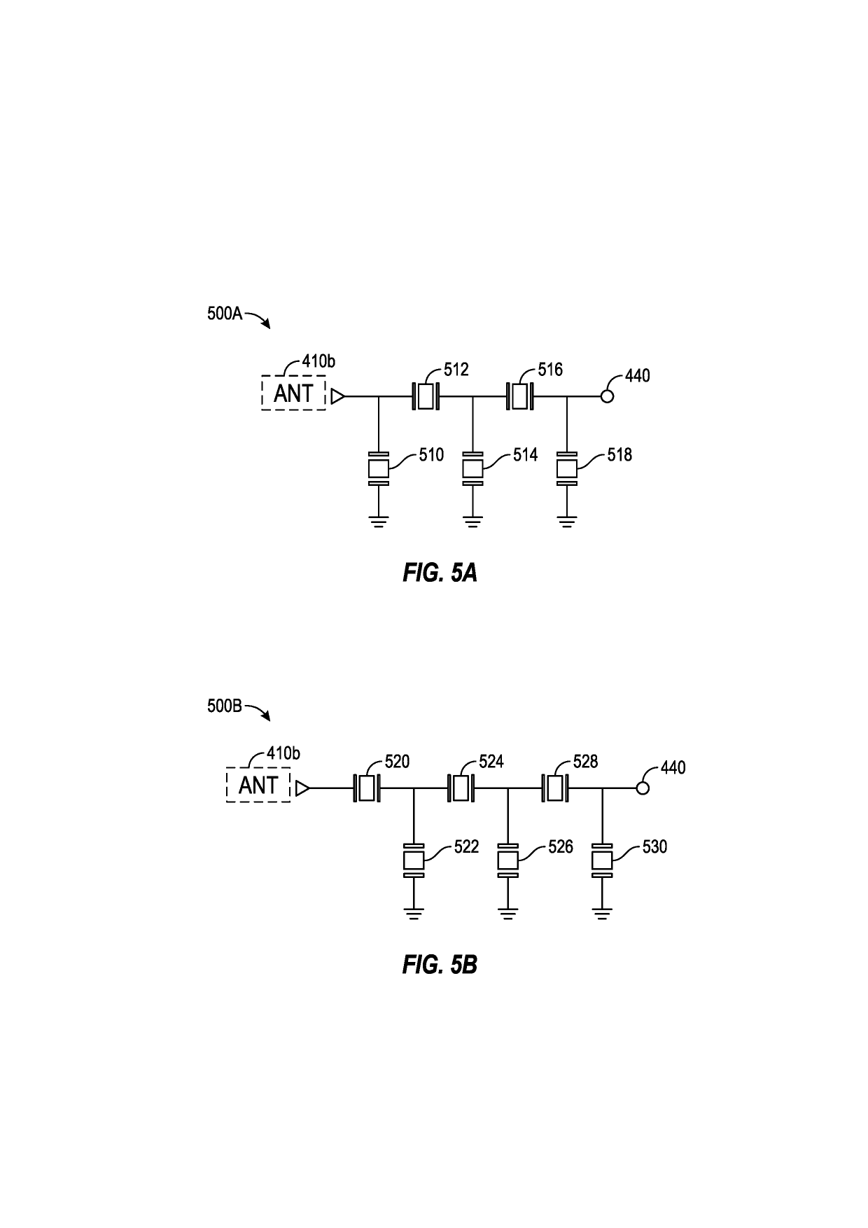

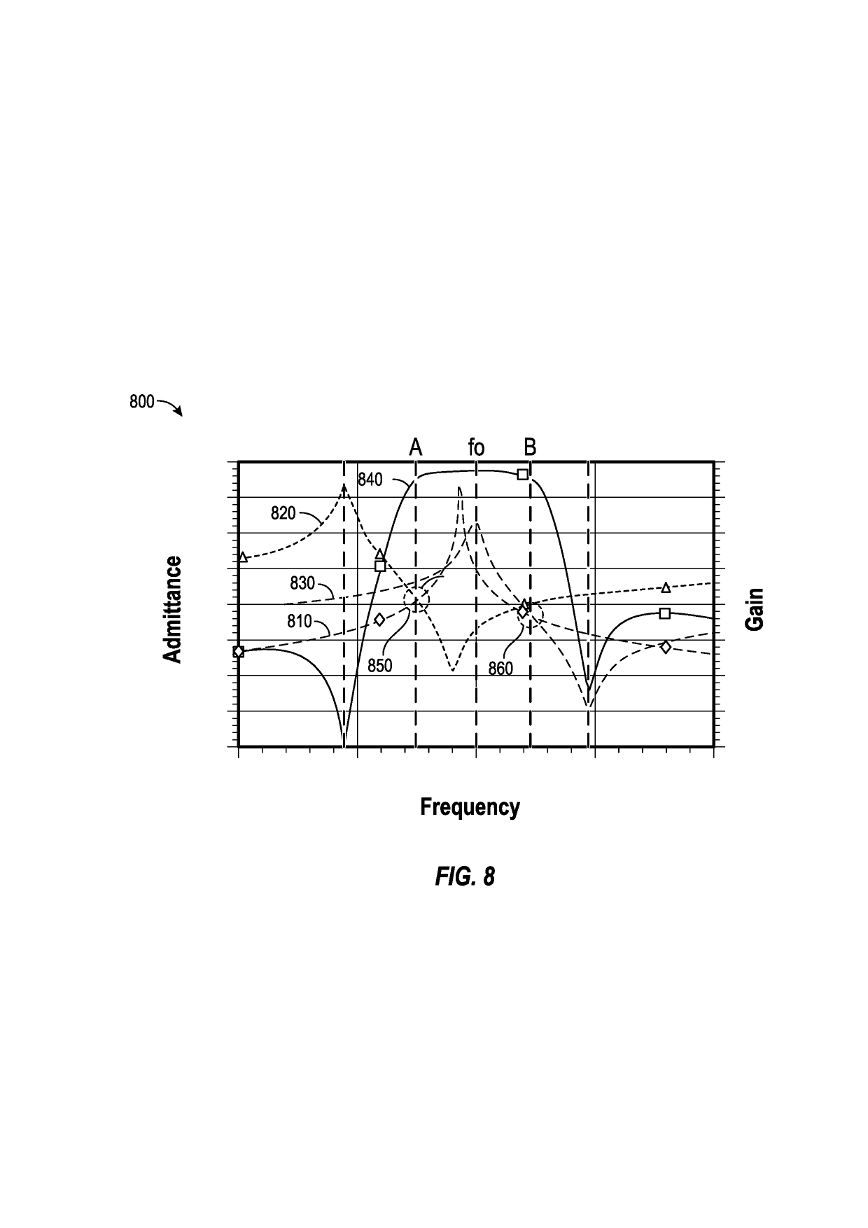

In a filtenna, the first resonator of the considered filter topology is the antenna itself (e.g., the radiating element). This sets boundary conditions for the following stages. If the antenna is designed to operate at its series resonance, then the following acoustic resonator of the filtenna should be a parallel resonance circuit (the antenna is considered as the first resonator, having series resonance). FIG. 5A is a circuit diagram of a filtenna 500A where the antenna 410b (labeled “ANT”) is designed to operate at its series resonance, in accordance with certain aspects of the present disclosure. In this case, an acoustic resonator 510 coupled in shunt may follow the antenna 410b, as shown. If the antenna 410b is designed to operate at its parallel resonance, then the following acoustic resonator 510 of the filtenna should be a series resonance circuit (the antenna 410b is considered as the first resonator, having parallel resonance). FIG. 5B is a circuit diagram of a filtenna 500B where the antenna 410b is designed to operate at its parallel resonance, in accordance with certain aspects of the present disclosure. In this case, an acoustic resonator 520 may be coupled in series with the antenna 410b, as shown. In either case, the resonance of the antenna 410b is designed as part of the overall filtenna filter response and may be offset from the center frequency of the filtenna’s frequency band (as is also described below with respect to FIG. 8), unlike in some approaches where the antenna is designed independently from the filter circuit and may have a resonance at the center frequency. In this manner, the antenna 410b (used as the first resonator) and the one or more acoustic resonators together may form a combined filter circuit having a passband (or other desired filter response (e.g., low pass, high pass, notch, or bandstop)) corresponding to the target operating frequency band of the filtenna.

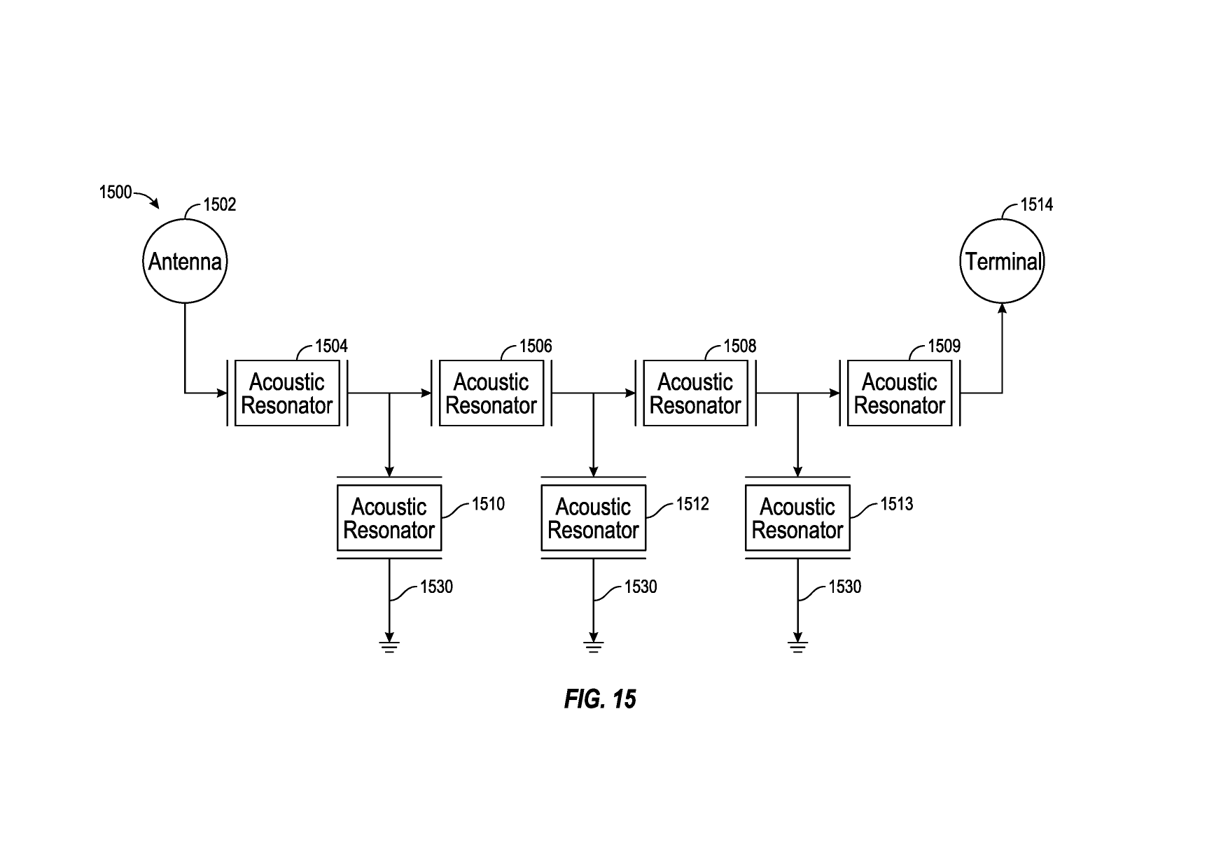

Multiple resonators can be coupled together, following a ladder-type architecture (e.g., as shown in FIGS. 5A, 5B, and 15) in a filtenna to achieve higher-order filters and a particular filter transfer function. For example, a filtenna may include a ladder-type architecture with the antenna 410b (used as the first resonator with series resonance) and with shunt acoustic resonators 510, 514, 518 and series acoustic resonators 512, 516 coupled in an alternating fashion between the antenna 410b and the port 440, as shown in the filtenna 500A of FIG. 5A. That is, in a ladder-type architecture, series acoustic resonator 512 follows shunt acoustic resonator 510, shunt acoustic resonator 514 follows series acoustic resonator 512, and so forth. In another example, a filtenna may include a ladder-type architecture with the antenna 410b (used as the first resonator with parallel resonance) and with series acoustic resonators 520, 524, 528, and shunt acoustic resonators 522, 526, 530 coupled in an alternating fashion between the antenna 410b and the port 440, as shown in the filtenna 500B of FIG. 5B. As described above, the acoustic resonators may be implemented by any of various suitable devices, such as BAW resonators (including FBARs and SMRs), SAW resonators, MEMS devices, or any combination thereof.

In case the coupling of the acoustic resonators (e.g., acoustic resonators 510, 512, 514, 516, 518, 520, 522, 524, 526, 528, and/or 530) is insufficient to achieve a particular filter design, inductors coupled in parallel with at least some of the acoustic resonators may correct, or at least adjust for this situation. Additionally or alternatively, inductors connected in series with the acoustic resonators (e.g., shunt acoustic resonators and/or series acoustic resonators) may improve the filtenna performance, such as in cases where the technology-defined micro-acoustic resonator gap (between series resonance and parallel resonance) would not be sufficient to cover the entire filtenna bandwidth. Furthermore, capacitors may be coupled either in series or in parallel with the acoustic resonators.

If the port 440 should be matched to the characteristic impedance (e.g., 50 Ω) of the RFFE, an impedance converter (not illustrated) may be coupled to the port 440. An impedance converter may be implemented, in its simplest form, as a two-element inductor-capacitor (LC) network, while other implementations with different LC configurations or impedance converter circuits are contemplated.

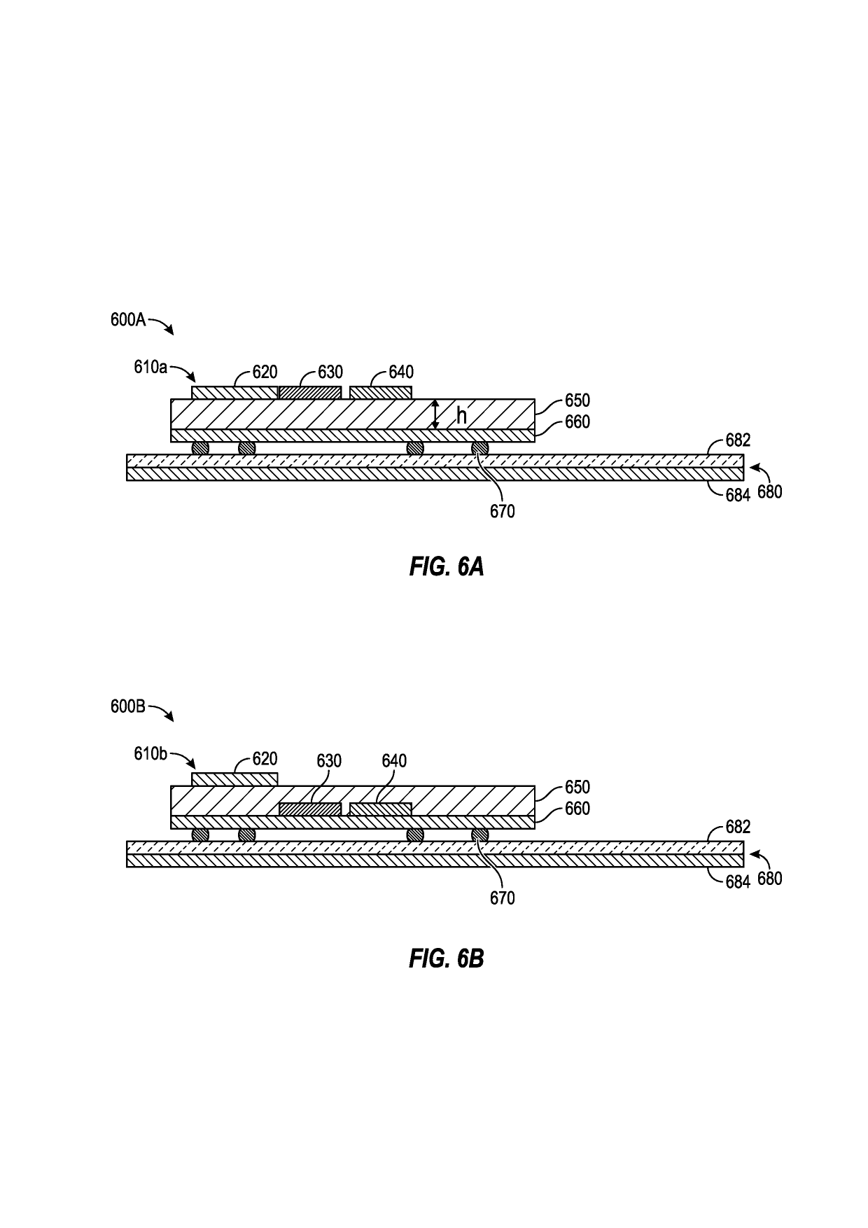

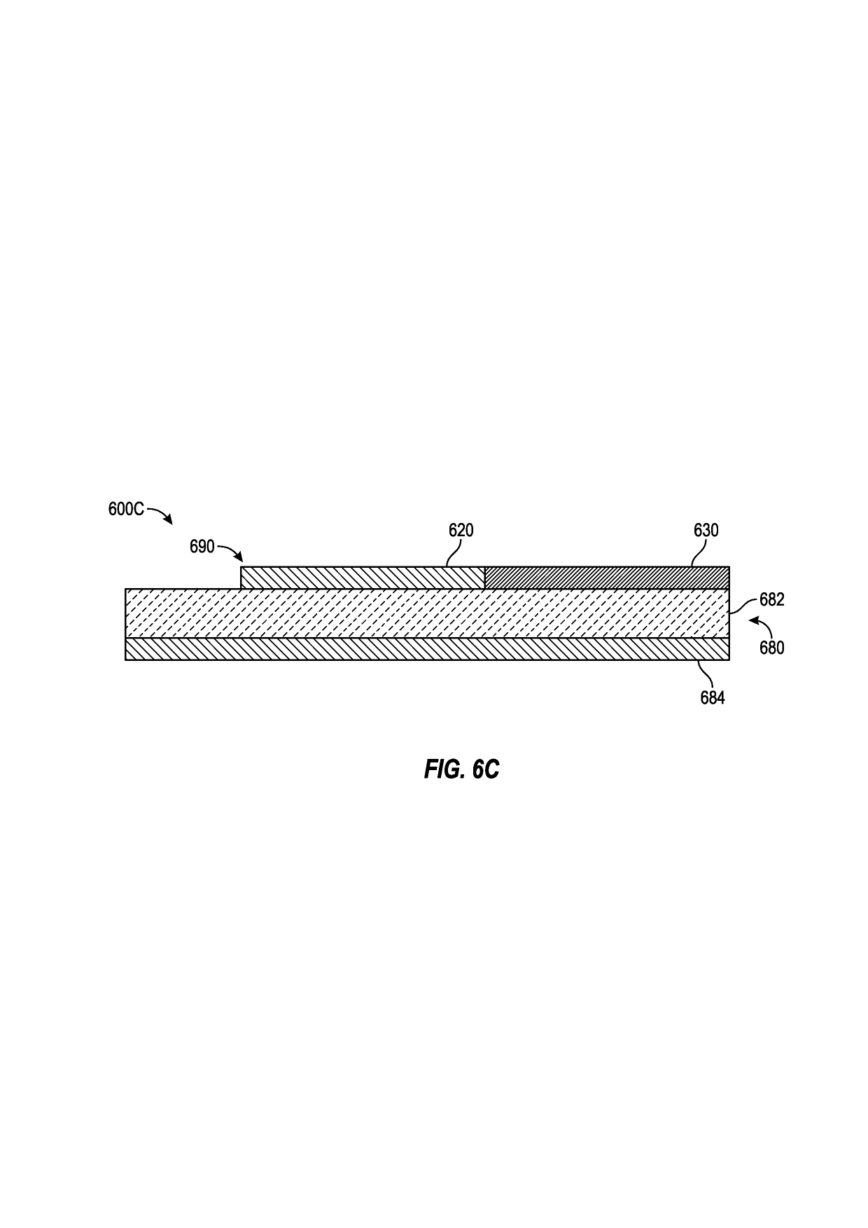

FIG. 6A is a cross-sectional view of an example module 600A including a filtenna submodule 610a disposed above a printed circuit board (PCB) 680, in accordance with certain aspects of the present disclosure. In the filtenna submodule 610a, an antenna 620 (e.g., being or including a radiating element, such as a patterned metal radiating element) and an acoustic chip 630 (with one or more acoustic resonators) are disposed adjacent to one another above a substrate 650. In some aspects, the antenna 620 may be electrically coupled to the one or more acoustic resonators of the acoustic chip 630. The antenna 620 and the other antennas described herein may be implemented, for example, by patch antennas, inverted-L antennas, inverted-F antennas (e.g., planar inverted-F antennas), inverted-V antennas, or the like. When the antenna 620 is implemented with a patch antenna as a radiating element, the radiating element may be implemented in the form of a rectangle, a square, a circular disc, a ring, a triangle, a dipole, or any of other various suitable forms.

The substrate 650 may be implemented with a dielectric layer (e.g., a high-Q dielectric layer) having a height h, as shown. The substrate 650 may be disposed above a metal layer 660, which may include one or more electrically conductive traces and/or planes. At least part of the metal layer 660 may function as an antenna ground plane or a filtenna ground plane. The trace(s) and/or plane(s) in metal layer 660 may be coupled to one or more solder balls 670 or other suitable electrically conductive structures for coupling the filtenna submodule 610a to the PCB 680 to form the module 600A. The PCB 680 may include a dielectric layer 682 disposed above a metal layer 684 (e.g., a ground plane layer). The PCB 680 may also include one or more traces (not illustrated) disposed above the dielectric layer 682. These traces may include conductive pads in the PCB 680, which may be soldered or otherwise coupled to the solder balls 670 of the filtenna submodule 610a to mechanically attach and electrically couple the filtenna submodule 610a to the PCB 680 to form the module 600A. The location of the filtenna submodule 610a on the PCB 680 may be flexible.

In some cases, the PCB 680 may be part of wireless device PCB (e.g., a smartphone PCB) that includes multiple dielectric layers and multiple metal layers. In these cases, the filtenna submodule 610a may be soldered (or otherwise attached with suitable electrical connection) directly onto the wireless device PCB that includes the PCB 680.

In some aspects, one or more active devices 640 (e.g., a power amplifier (PA), a low noise amplifier (LNA), a switch, or the like) may optionally be included in the module 600A. In such cases, the active device(s) 640 may be disposed above the substrate 650 in the filtenna submodule 610a, such as adjacent to the acoustic chip 630.

FIG. 6B is a cross-sectional view of an example module 600B including a filtenna submodule 610b, in accordance with certain aspects of the present disclosure. The module 600B may be similar to the module 600A, and may include the antenna 620 (e.g., a patterned metal radiating element), the acoustic chip 630, one or more active devices 640, substrate 650, the metal layer 660, the one or more solder balls 670, and the PCB 680 with the dielectric layer 682 and the metal layer 684. In the module 600B, however, the antenna 620 is disposed above the substrate 650 of the filtenna submodule 610b, whereas the acoustic chip 630 is buried in the substrate 650 and disposed above the metal layer 660. The optional active device(s) 640 may also be buried in the substrate 650 and disposed above the metal layer 660, as shown.

FIG. 6C is a cross-sectional view of an example module 600C including a filtenna 690, in accordance with certain aspects of the present disclosure. The module 600C may include the antenna 620, the acoustic chip 630, and the PCB 680 with the dielectric layer 682 and the metal layer 684. Unlike the modules 600A, 600B, the module 600C may not include a filtenna submodule disposed above the PCB 680 and coupled thereto with solder balls 670. Instead, the module 600C, the antenna 620, the acoustic chip 630, and/or optional active device(s) 640 (not illustrated) of the filtenna 690 may be disposed directly on the PCB 680. In this manner, the height of the module 600C may be equal to or not much greater than the height of the PCB 680.

In certain aspects, the one or more acoustic resonators included in the acoustic chip 630 may be formed on one die and separated from the antenna 620 (where the antenna may be formed on another die and may be used as one resonator of the filtenna). In other aspects, the antenna 620 and the one or more acoustic resonators in the acoustic chip 630 may be packaged in a common package. The antenna 620 and the one or more acoustic resonators in the acoustic chip 630 may be co-located together such that a conductive line coupling the antenna 620 to the one or more acoustic resonators forms a portion of the antenna 620.

Optionally a phase shifter can be added and coupled to the filtenna in any of the modules 600A, 600B, 600C. This optional phase shifter may be included, for example, in cases where the module is part of a more complex phased-array configuration.

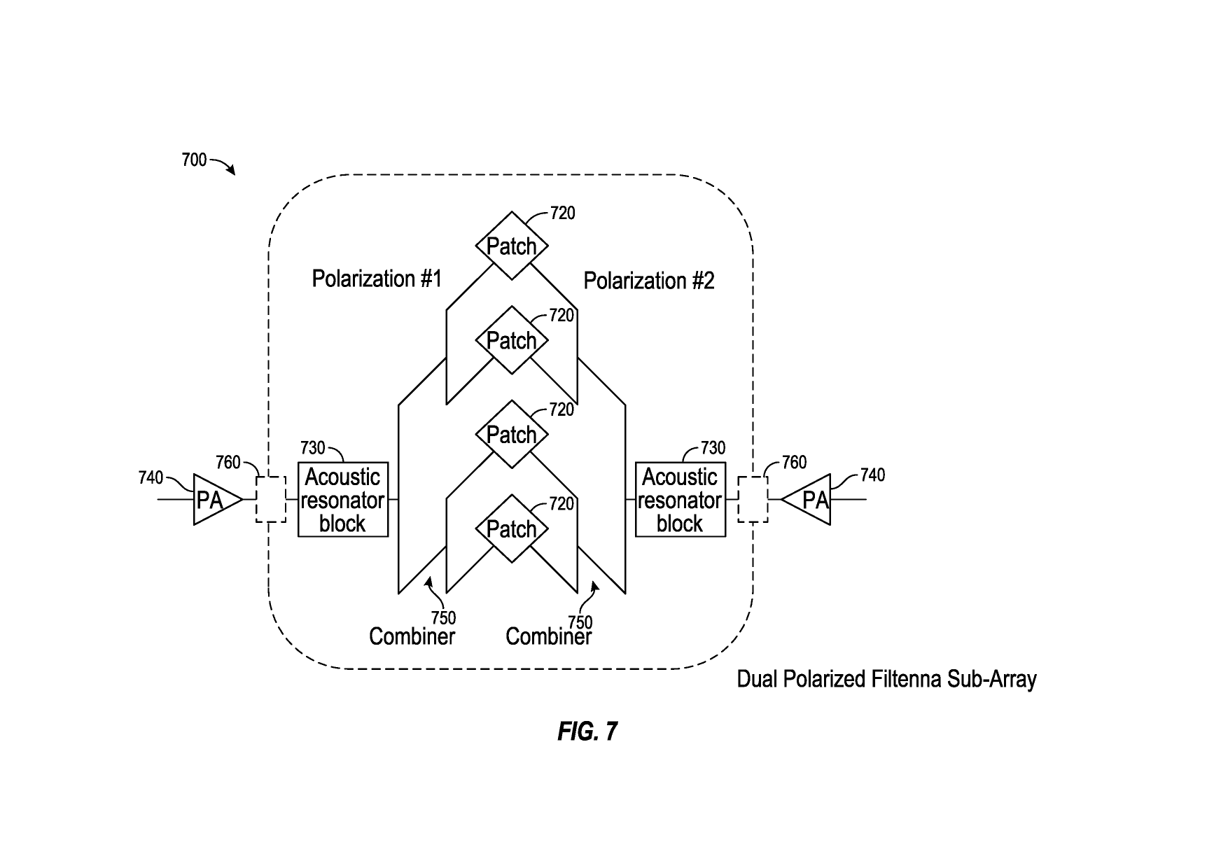

FIG. 7 is a block diagram depicting an example dual-polarized filtenna sub-array 700 for phased-array applications, in accordance with certain aspects of the present disclosure. The dual-polarized filtenna sub-array 700 may include multiple antennas 720 (each labeled “Patch”), acoustic resonator blocks 730 (each with one or more acoustic resonators), and combiners 750. As illustrated, the acoustic resonator blocks 730 of the filtenna sub-array 700 may be coupled to active devices 740 (e.g., amplifiers, such as PAs as shown). Although not illustrated, the dual-polarized filtenna sub-array 700 may also be coupled to additional active devices (e.g., PAs, LNAs, switches, etc.). In certain aspects, the dual-polarized filtenna sub-array 700 may include or be coupled to one or more optional impedance converters 760. The dual-polarized filtenna sub-array 700 may support two linear polarizations (e.g., Polarization #1 and Polarization #2), as shown.

FIG. 8 is a frequency spectrum 800 illustrating a distribution of example frequency responses and resonance frequencies associated with a single-band filtenna (e.g., a three-pole filtenna), in accordance with certain aspects of the present disclosure. The spectrum 800 illustrates an admittance of an antenna 810, an admittance of an acoustic resonator in shunt 820, and an admittance of an acoustic resonator in series 830, over frequency. When combined, the admittance of the antenna 810, the admittance of the acoustic resonator in shunt 820, and the admittance of the acoustic resonator in series 830, over frequency, may form a passband of a bandpass frequency response of a filtenna 840 (e.g., a filter transfer function of the filtenna, illustrating gain over frequency). The passband may be characterized by a center frequency (e.g., labeled “f0”) and a bandwidth (e.g., the range from frequency A to frequency B). The passband of the frequency response of the filtenna 840 may be approximately defined by an intersection 850 of the admittances of the antenna 810 and the acoustic resonator in shunt 820 (e.g., at frequency A) below the center frequency and an intersection 860 of the admittances of the antenna 1110 and the acoustic resonator in series 830 (e.g., at frequency B) above the center frequency. In some cases, the passband of the filtenna may range from 12752 MHz to 13229 MHz.

### Example Dual-Band Filtenna with Micro-Acoustic Resonators

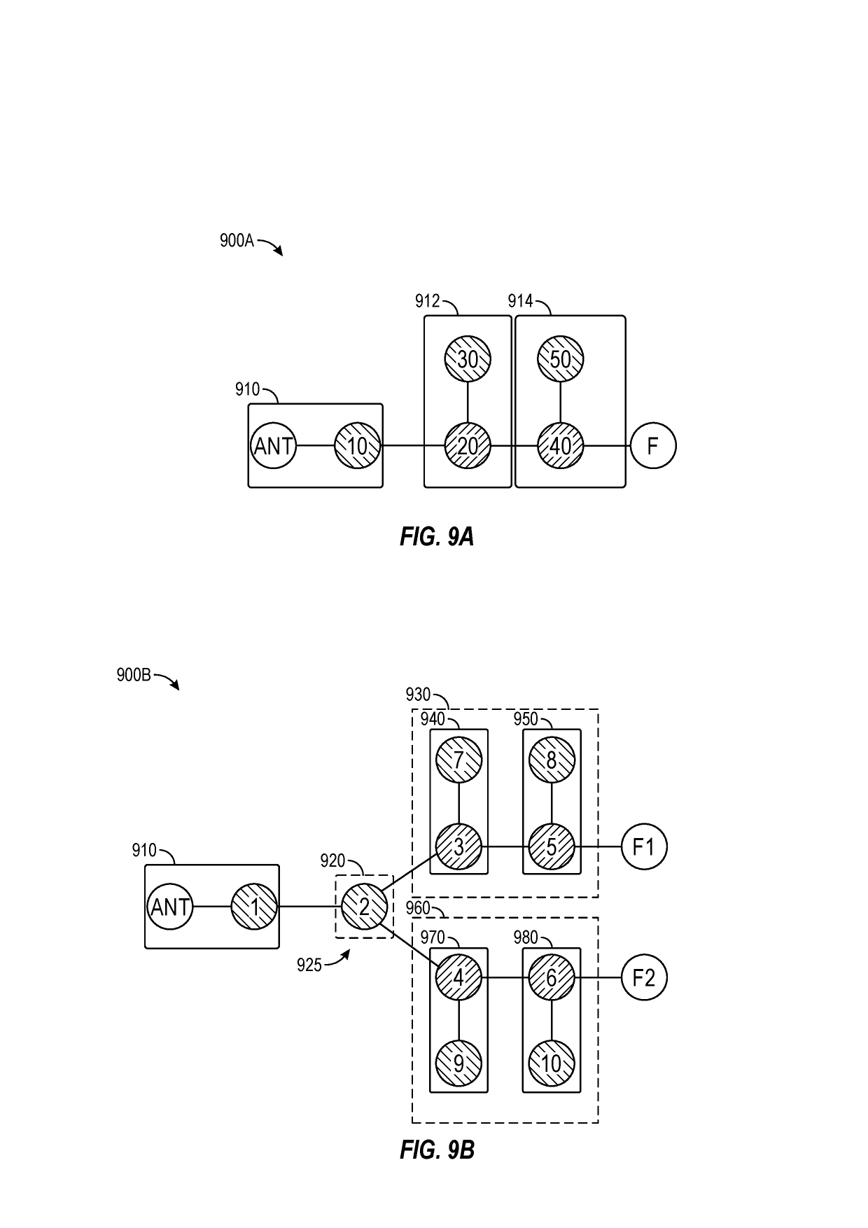

According to certain aspects, a filtenna may utilize acoustic resonators (e.g., micro-acoustic resonators), each with a resonant node and non-resonant node representing the two resonances (e.g., series and parallel resonance frequencies) within the acoustic resonators. The series resonance frequency occurs at the minimum impedance point of an acoustic resonator, while the parallel resonance frequency occurs at the maximum impedance point of the acoustic resonator. FIG. 9A is a block diagram of a single-band filtenna 900A, as described above. The filtenna 900A may include an antenna 910 (e.g., having series resonance), an acoustic resonator 912 (e.g., having parallel resonance), and an acoustic resonator 914 (e.g., having series resonance), as illustrated. The antenna 910 may include one or more antenna elements (labeled “ANT”) coupled to a resonant node 10 (e.g., the antenna element(s) and resonance node 10 collectively implementing a radiating element with series resonance). The acoustic resonator 912 may include a non-resonant node 20 and a resonant node 30 both coupled to the resonant node 10, and the acoustic resonator 914 may include a non-resonant node 40 and a resonant node 50 both coupled to the non-resonant node 20. The acoustic resonator 914 may be coupled to (a remaining portion of) a filter (via a port labeled “F”), as shown.

In certain aspects, the connecting lines between illustrated elements (e.g., in between resonant and non-resonant nodes) may represent impedance-inverters contributing to the implementation of the antenna 910, the acoustic resonator 912, and the acoustic resonator 914. For example, the antenna 910 may be modeled as a lossy series resonance circuit and may be composed of the one or more antenna elements ANT (representing the real part of the antenna 910 impedance), an interconnect coupled between the one or more antenna elements ANT and the resonant node 10, the resonant node 10, and an interconnect coupled between the resonant node 10 and the non-resonant node 20. As another example, the acoustic resonator 912 may be composed of the non-resonant node 20, an interconnect coupled between the non-resonant node 20 and the resonant node 30, and the resonant node 30. As yet another example, the acoustic resonator 914 may be composed of an interconnect coupled between the non-resonant node 20 and the non-resonant node 40, the non-resonant node 40, an interconnect coupled between the non-resonant node 40 and the resonant node 50, the resonant node 50, and an interconnect coupled between the non-resonant node 40 and (the remaining portion of) the filter (via port F). It is to be understood that even though every individual interconnect may not be explicitly shown or described herein, interconnects may be part of the resonators and other elements described herein.

According to certain aspects of the present disclosure, the filtenna described herein may be expanded to a multiband filtenna to provide at least two frequency passbands, for more versatility. Referring to FIG. 9B, the multiband filtenna is a dual-band filtenna 900B and thus may include two filter branches (via ports labeled “F1” and “F2”). The filtenna 900B may also include the antenna 910 (e.g., used as a first resonator of the filtenna with series resonance), at least one acoustic resonator 920, a first filter branch 930, and a second filter branch 960.

The antenna 910 may include the one or more antenna elements (labeled “ANT”) and a resonant node 1, and may be coupled to the at least one acoustic resonator 920, which includes a resonant node 2. The first filter branch 930 and the second filter branch 960 may be coupled to the at least one acoustic resonator 920, as illustrated. The first filter branch 930 may include an acoustic resonator 940 (e.g., having series resonance), which includes a non-resonant node 3 and a resonant node 7, and an acoustic resonator 950 (e.g., having parallel resonance), which includes a non-resonant node 5 and a resonant node 8. The second filter branch 960 may include an acoustic resonator 970 (e.g., having series resonance), which includes a non-resonant node 4 and a resonant node 9, and an acoustic resonator 980 (e.g., having parallel resonance), which includes a non-resonant node 6 and a resonant node 10. The antenna 910, the at least one acoustic resonator 920, and the first filter branch 930 may form at least a portion of a first filter (e.g., having a particular first filter transfer function) of the dual-band filtenna 900B, whereas the antenna 910, the at least one acoustic resonator 920, and the second filter branch 960 may form at least a portion of a second filter (e.g., having a particular second filter transfer function) of the dual-band filtenna 900B. The second filter may be configured to have a different passband (or other filter transfer function) than the first filter. The first filter branch 930 may be coupled to a remaining portion of the first filter via port F1, and the second filter branch 960 may be coupled to a remaining portion of the second filter via port F2.

The at least one acoustic resonator 920 may be coupled to the antenna 910, the first filter branch 930, and the second filter branch 960 at a common node 925. In certain aspects, the common node 925 may be a common voltage node at relatively low frequencies (e.g., from DC to baseband frequencies). Certain aspects of the present disclosure may provide various implementations of the at least one acoustic resonator 920 at the common node 925.

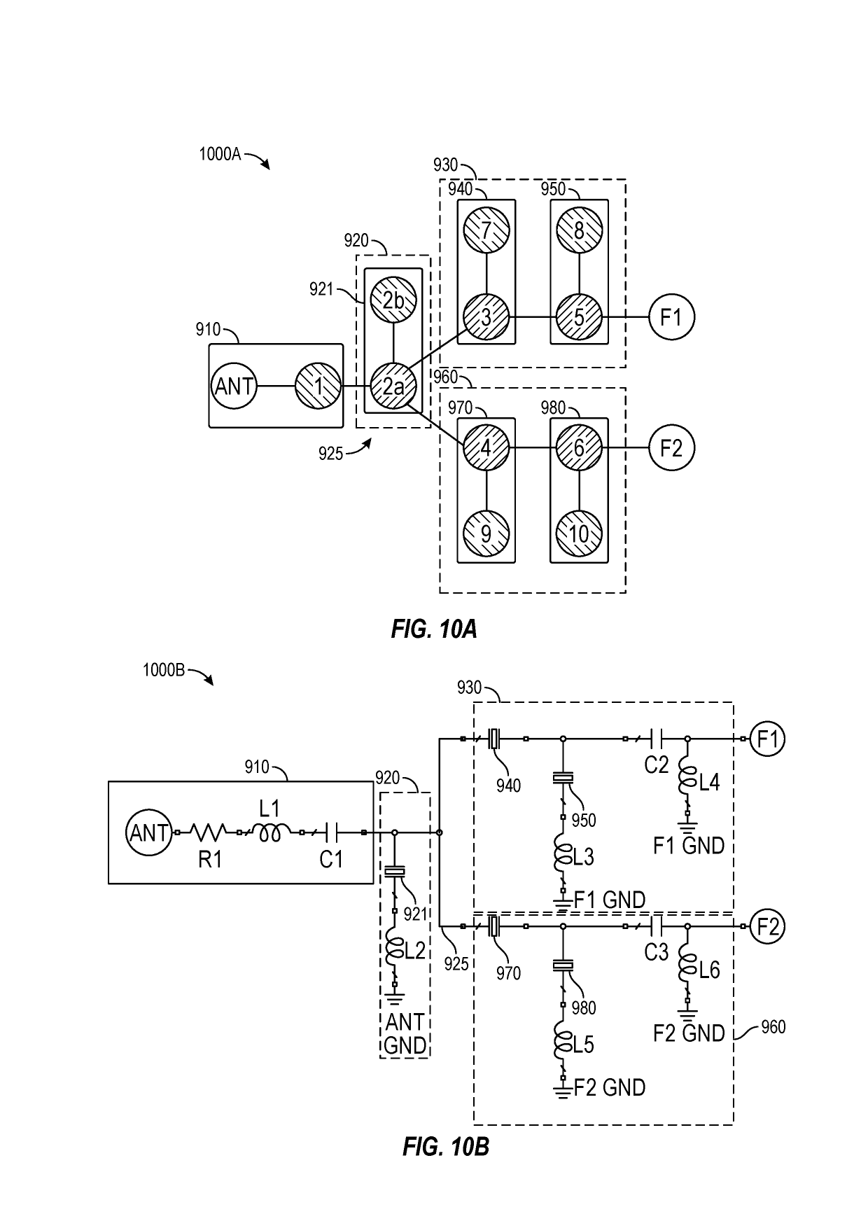

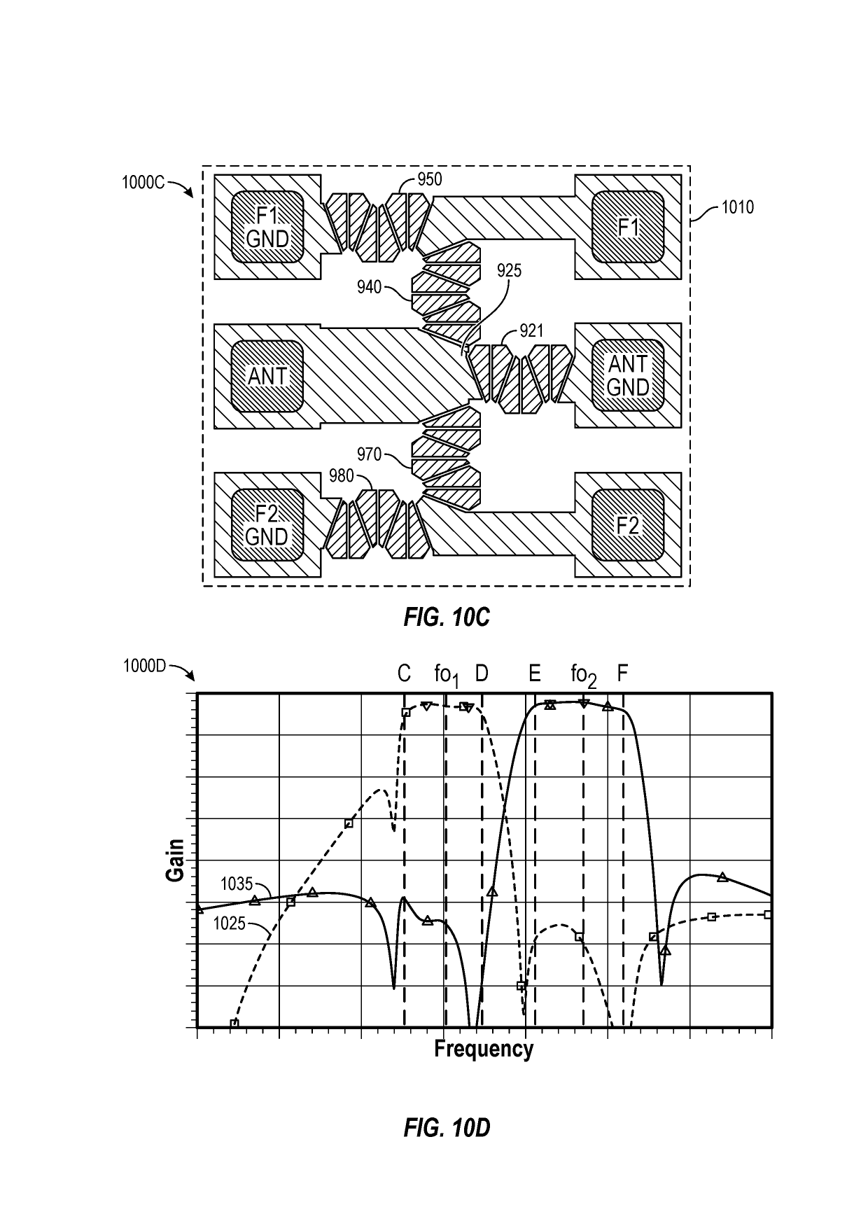

FIGS. 10A, 11A, and 12A are block diagrams depicting example dual-band filtennas 1000A, 1100A, 1200A, respectively, in accordance with certain aspects of the present disclosure. FIGS. 10B, 11B, and 12B are schematic diagrams of example dual-band filtennas 1000B, 1100B, 1200B, respectively, in accordance with certain aspects of the present disclosure. The dual-band filtennas 1000B, 1100B, 1200B may be schematic representations of the block diagrams of dual-band filtenna 1000A, 1000B, 1000C, respectively. FIGS. 10C, 11C, 11D, and 12C are top views of example acoustic chip layouts depicting example dual-band filtennas 1000C, 1100C, 1100D, 1200C, in accordance with certain aspects of the present disclosure. The dual-band filtennas 1000C, 1100C, 1200C may be top views of the layouts of dual-band filtennas 1000A/1000B, 1100A/1100B, 1200A/1200B, respectively. Dual-band filtenna 1100D may be a top view of an alternative layout of dual-band filtenna 1100A/1100B using separate dies.

### Example Dual-Band Filtenna with a Common Shunt Resonator

Referring to FIG. 10A, the dual-band filtenna 1000A may be similar to the dual-band filtenna 900B and may thus include the antenna 910, the first filter branch 930, the second filter branch 960, a remaining portion of the first filter via port F1, and a remaining portion of the second filter via port F2. In the dual-band filtenna 1000A, however, the at least one acoustic resonator 920 may be implemented with an acoustic resonator 921 (including non-resonant node 2a and resonant node 2b) disposed adjacent to the antenna 910. The acoustic resonator 921 may be coupled to the antenna 910, to the first filter branch 930, and to the second filter branch 960 at the common node 925, as illustrated. In this manner, the single acoustic resonator 921 is common to the first filter and the second filter (and is commonly coupled to the first filter branch 930 and the second filter branch 960). Thus, the acoustic resonator 921 may be referred to as a “common acoustic resonator.” The acoustic resonator 921 may have parallel resonance when the antenna 910 has series resonance, and vice versa. In some cases, the series resonance of the acoustic resonator 921 may be configured to be below the passband of the filter branch which provides the lowest passband frequency to help avoid deterioration of the passbands provided by the dual-band filtenna 1000A.

Referring to FIG. 10B, the dual-band filtenna 1000B may include the antenna 910, the at least one acoustic resonator 920, the first filter branch 930, the second filter branch 960, a remaining portion of the first filter via port F1, and a remaining portion of the second filter via port F2. The antenna 910 may include or may be represented by the one or more antenna elements ANT coupled to a resistive element R1 (which may be a parasitic resistance), an inductive element L1 coupled in series with the resistive element R1, and a capacitive element C1 coupled in series with the inductive element L1. The at least one acoustic resonator 920 may be implemented with the acoustic resonator 921, which may be coupled between the common node 925 and a first reference potential node (e.g., a first electrical ground, labeled “ANT GND” as shown). In some cases, the ANT GND node may be associated (e.g., shared) with the antenna 910. In some cases, an inductive element L2 may be coupled between the acoustic resonator 921 and the ANT GND node.

The first filter branch 930 may include the acoustic resonator 940 and the acoustic resonator 950. The acoustic resonator 940 may be coupled in series with the common node 925, and the acoustic resonator 950 may be coupled in shunt between the acoustic resonator 940 and a second reference potential node (e.g., a second electrical ground, labeled “F1 GND” as illustrated). The F1 GND node may be associated (e.g., shared) with the first filter branch 930 including the port F1. In some cases, an inductive element L3 may be coupled between the acoustic resonator 950 and the F1 GND node. The first filter branch 930 may also include (i) a capacitive element C2 coupled in series between the acoustic resonator 940 and the acoustic resonator 950 and (ii) an inductive element L4 coupled in shunt between the capacitive element C2 and the F1 GND node, as illustrated.

The second filter branch 960 may include the acoustic resonator 970 and the acoustic resonator 980. The acoustic resonator 970 may be coupled in series with the common node 925, and the acoustic resonator 980 may be coupled in shunt between the acoustic resonator 970 and a third reference potential node (e.g., a third electrical ground, labeled “F2 GND” as illustrated). The F2 GND node may be associated (e.g., shared) with the second filter branch 960 including the port F2. In some cases, an inductive element L5 may be coupled between the acoustic resonator 980 and the F2 GND node. The second filter branch 960 may also include (i) a capacitive element C3 coupled in series between the acoustic resonator 970 and the acoustic resonator 980 and (ii) an inductive element L6 coupled in shunt between the capacitive element C3 and the F2 GND node, as illustrated. In certain aspects, the ANT GND node, the F1 GND node, and the F2 GND node are different nodes (e.g., separate grounds), for example, to help avoid cross-coupling.

The dual-band filtenna 1000C of FIG. 10C may be an example acoustic chip layout of the dual-band filtenna 1000A/1000B of FIG. 10A/10B. As depicted in FIG. 10C, the acoustic resonator 921, the first filter branch 930 (including acoustic resonators 940 and 950 and the F1 GND node), the second filter branch 960 (including acoustic resonators 970 and 980 and the F2 GND node) may be disposed on a single acoustic die 1010. As described above, the acoustic resonator 921 is coupled in shunt between the common node 925 and the ANT GND node. The first filter branch 930 (starting with the acoustic resonator 940) is coupled to the common node 925, and the second filter branch 960 (starting with the acoustic resonator 970) is also coupled to the common node 925. The acoustic resonator 950 is coupled in shunt to the F1 GND node, and the acoustic resonator 980 is coupled in shunt to the F2 GND node. The ANT GND node, the F1 GND node, and the F2 GND node are all separate ground nodes for the dual-band filtenna 1000C. For purposes of illustration, each of the acoustic resonators 921, 940, 950, 970, and 980 are depicted as a number of cascaded BAW resonators (top view), but it should be appreciated that other acoustic resonator implementations are possible (e.g., SAW types, non-cascaded, and the like).

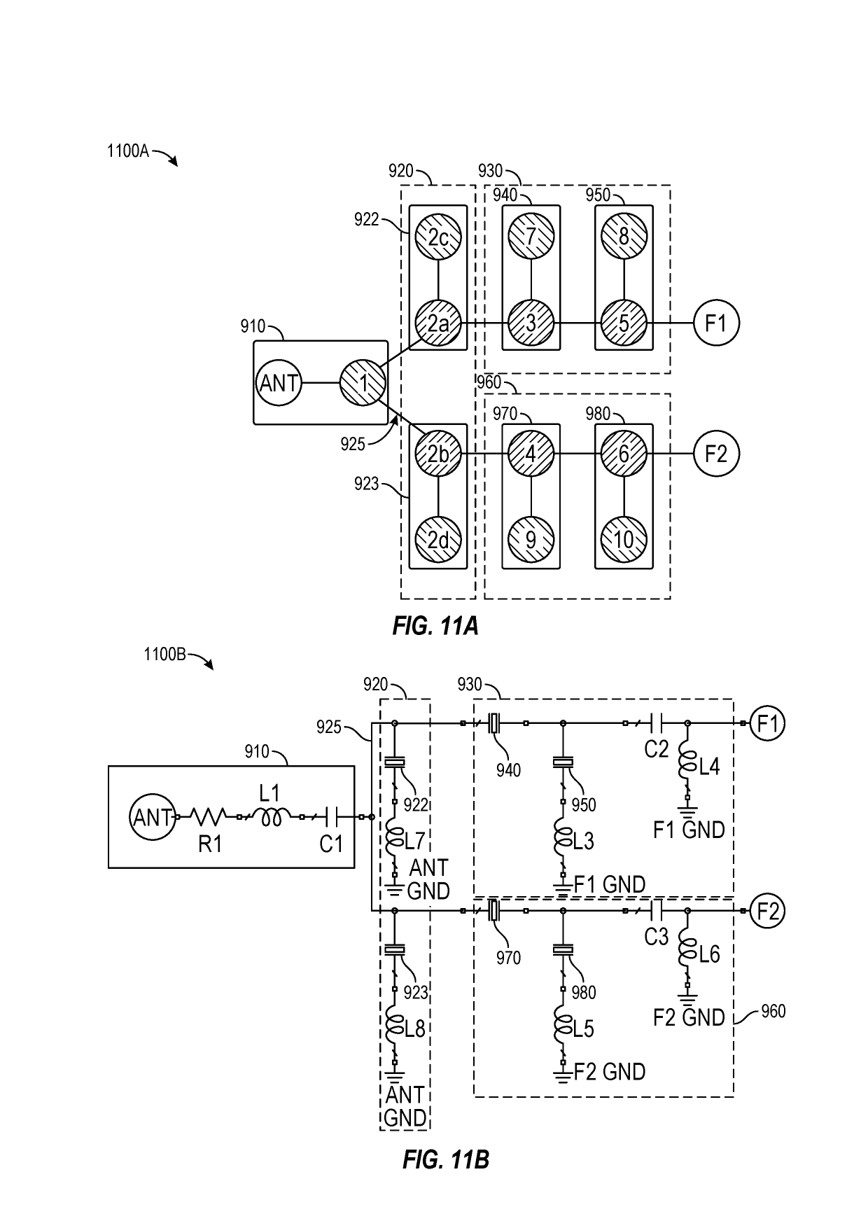

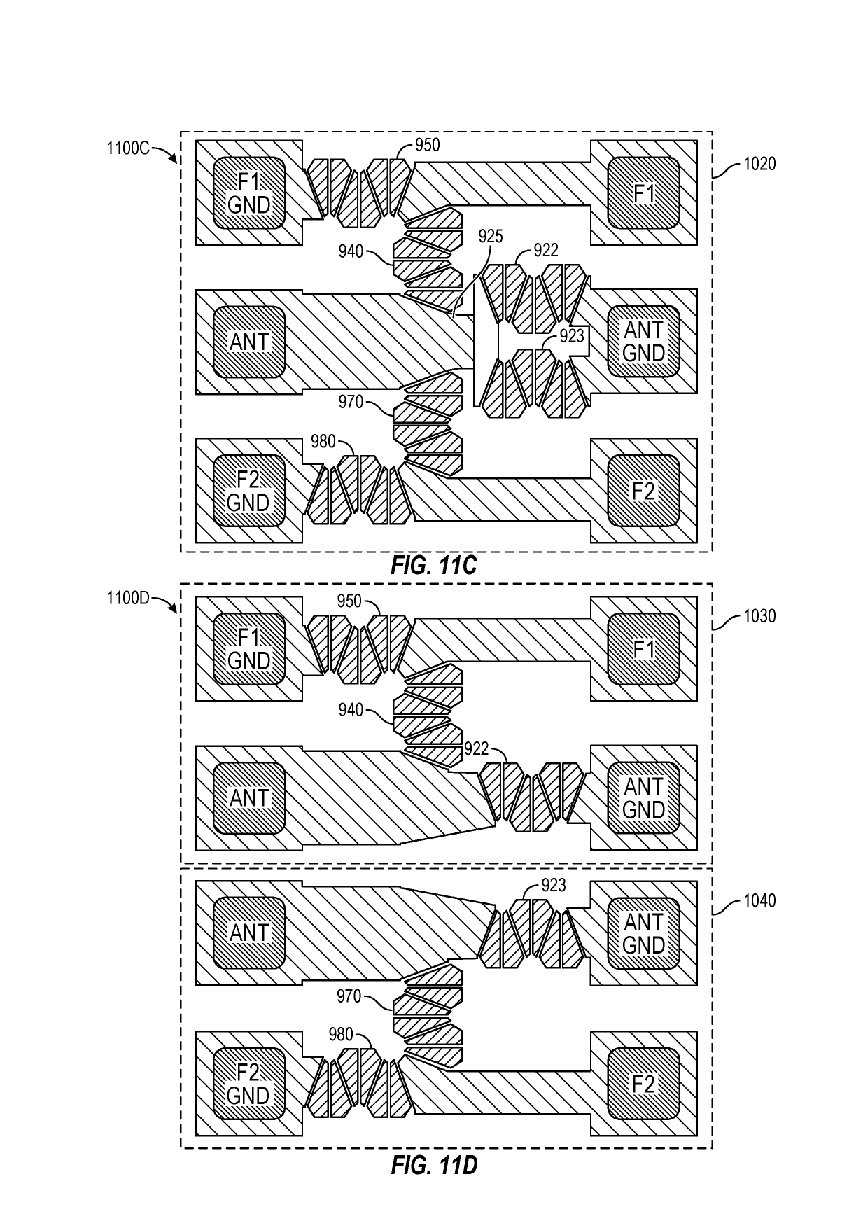

FIG. 10D is a frequency spectrum 1000D illustrating a distribution of example frequency responses and resonance frequencies associated with a dual-band filtenna, in accordance with certain aspects of the present disclosure. The spectrum 1000D illustrates a first passband of a frequency response 1025 of a first filter branch of a dual-band filtenna (e.g., a first filter transfer function of the dual-band filtenna, illustrating gain over frequency). The frequency response 1025 may be a combination of an admittance of an antenna, an admittance of at least one acoustic resonator (e.g., the acoustic resonator 921 in shunt in FIGS. 10A-10C or the acoustic resonator 922 in shunt in FIGS. 11A-11D), an admittance of one or more acoustic resonators in shunt in the first filter branch, and an admittance of one or more acoustic resonators in series in the first filter branch. The first passband may be characterized by a first center frequency (e.g., labeled “f0₁”) and a first bandwidth (e.g., the range from frequency C to frequency D).

The spectrum 1000D also illustrates a second passband of a frequency response 1035 of a second filter branch of the dual-band filtenna (e.g., a second filter transfer function of the dual-band filtenna, illustrating gain over frequency). The frequency response 1035 may be a combination of an admittance of the antenna, an admittance of the at least one acoustic resonator (e.g., the acoustic resonator 921 in shunt in FIGS. 10A-10C or the acoustic resonator 923 in shunt in FIGS. 11A-11D), an admittance of one or more acoustic resonators in shunt in the second filter branch, and an admittance of one or more acoustic resonators in series in the second filter branch. The second passband may be characterized by a second center frequency (e.g., labeled “f0₂”) and a second bandwidth (e.g., the range from frequency E to frequency F). As an example, the first passband may range from 17.8 GHz to 18.3 GHz, and the second passband may range from 19.3 GHz to 19.7 GHz.

### Example Dual-Band Filtenna with Dual Shunt Resonators

Referring to FIG. 11A, the dual-band filtenna 1100A may be similar to the dual-band filtenna 1000A, and thus may include the antenna 910, the first filter branch 930, the second filter branch 960, a remaining portion of the first filter via port F1, and a remaining portion of the second filter via port F2. In the dual-band filtenna 1100A, however, the at least one acoustic resonator 920 may be implemented with an acoustic resonator 922 (including non-resonant node 2a and resonant node 2c) and an acoustic resonator 923 (including non-resonant node 2b and resonant node 2d), both coupled to the antenna 910, to the first filter branch 930, and to the second filter branch 960 at the common node 925. In this manner, the resonant node 2 in the dual-band filtenna 900B of FIG. 9B has been replaced by four resonating elements 2a-2d in the dual-band filtenna 1100A of FIG. 11A. The acoustic resonators 922, 923 may have parallel resonance when the antenna 910 has series resonance, and vice versa. In certain aspects, a resonance frequency of the acoustic resonator 922 may be different than a resonance frequency of the acoustic resonator 923 (e.g., to better shape the bandpass slope of both filters, thereby leading to better performance provided by the dual-band filtenna 1100A).

Referring to FIG. 11B, the dual-band filtenna 1100B may be similar to the dual-band filtenna 1000B and thus may include the antenna 910 (which may operate at series resonance), the at least one acoustic resonator 920, the first filter branch 930, the second filter branch 960, a remaining portion of the first filter via port F1, and a remaining portion of the second filter via port F2. In the dual-band filtenna 1100B, however, the at least one acoustic resonator 920 may be implemented with the acoustic resonator 922 (having parallel resonance) and the acoustic resonator 923 (having parallel resonance) both coupled to the antenna 910, to the first filter branch 930, and to the second filter branch 960 at the common node 925. The acoustic resonator 922 may be coupled in shunt between the common node 925 and the ANT GND node, and the acoustic resonator 923 may be coupled in shunt between the common node 925 and the ANT GND node. In certain aspects, an inductive element L7 may be coupled between the acoustic resonator 922 and the ANT GND node, and/or an inductive element L8 may be coupled between the acoustic resonator 923 and the ANT GND node, as shown.

The dual-band filtenna 1100C of FIG. 11C may be an example acoustic chip layout of the dual-band filtenna 1100A/1100B of FIG. 11A/11B. As depicted in FIG. 11C, the acoustic resonators 922 and 923, the first filter branch 930 (including acoustic resonators 940 and 950 and the F1 GND node), the second filter branch 960 (including acoustic resonators 970 and 980 and the F2 GND node) may be disposed on a single acoustic die 1020. As described above, the acoustic resonator 922 is coupled in shunt between the common node 925 and the ANT GND node. Likewise, the acoustic resonator 923 is coupled in shunt between the common node 925 and the ANT GND node, such that the acoustic resonators 922, 923 are coupled in parallel on the die 1020. Other portions of the acoustic chip layout of the dual-band filtenna 1100C in FIG. 11C may be similar to the acoustic chip layout of the dual-band filtenna 1000C of FIG. 10C and are not further described here. As depicted, the ANT GND node is different (and spatially physically separated) from the F1 GND node and the F2 GND node.

According to certain aspects, utilizing two separate acoustic dies to implement a dual-band filtenna may be beneficial, for example, when the number of realizable frequencies on a single acoustic die is limited. The dual-band filtenna 1100D of FIG. 11D may be an example alternative acoustic chip layout of the dual-band filtenna 1100A/1100B of FIG. 11A/11B. As depicted in FIG. 11D, the acoustic resonator 922 and at least a portion of the first filter branch 930 (including acoustic resonators 940 and 950 and the F1 GND node) may be disposed on a first acoustic die 1030, whereas the acoustic resonator 923 and the second filter branch 960 (including acoustic resonators 970 and 980 and the F2 GND node) may be disposed on a second acoustic die 1040 different from the first acoustic die 1030. In each die, the ANT GND node is separated and different from the ground node associated with other shunt resonators 950 and 980 that are coupled to the series resonators 940 and 970 (e.g., ANT GND is separate from F1 GND or F2 GND within each die). In some aspects, the two different acoustic dies 1030 and 1040 are coupled to a common radiator (antenna element) via a connection point (e.g., the pads labeled “ANT”), and each of the first acoustic die 1030 and the second acoustic die 1050 includes a shunt resonator to a ground (labeled “ANT GND”) that is different and/or physically separate from another ground (e.g., F1 GND, F2 GND) that is connected to one or more shunt resonators coupled to a series resonator. Such physically separated grounds (e.g., ANT GND, F1 GND, and F2 GND) may assist in controlling current flow, minimizing loop area, and/or avoiding unintended group loops within the filtenna, thereby reducing noise and interference in the filtenna.

### Example Dual-Band Filtenna with Dual Shunt Resonators and Matching Element(s)

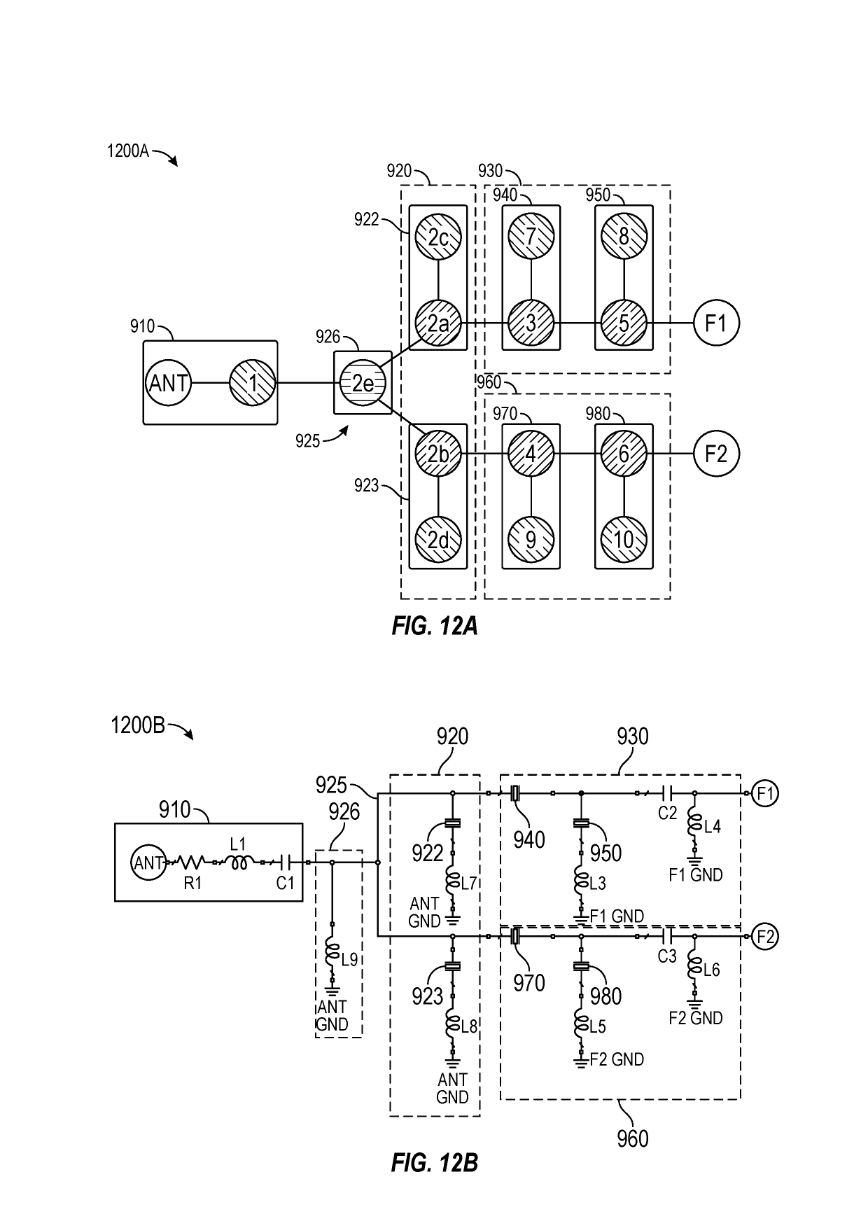

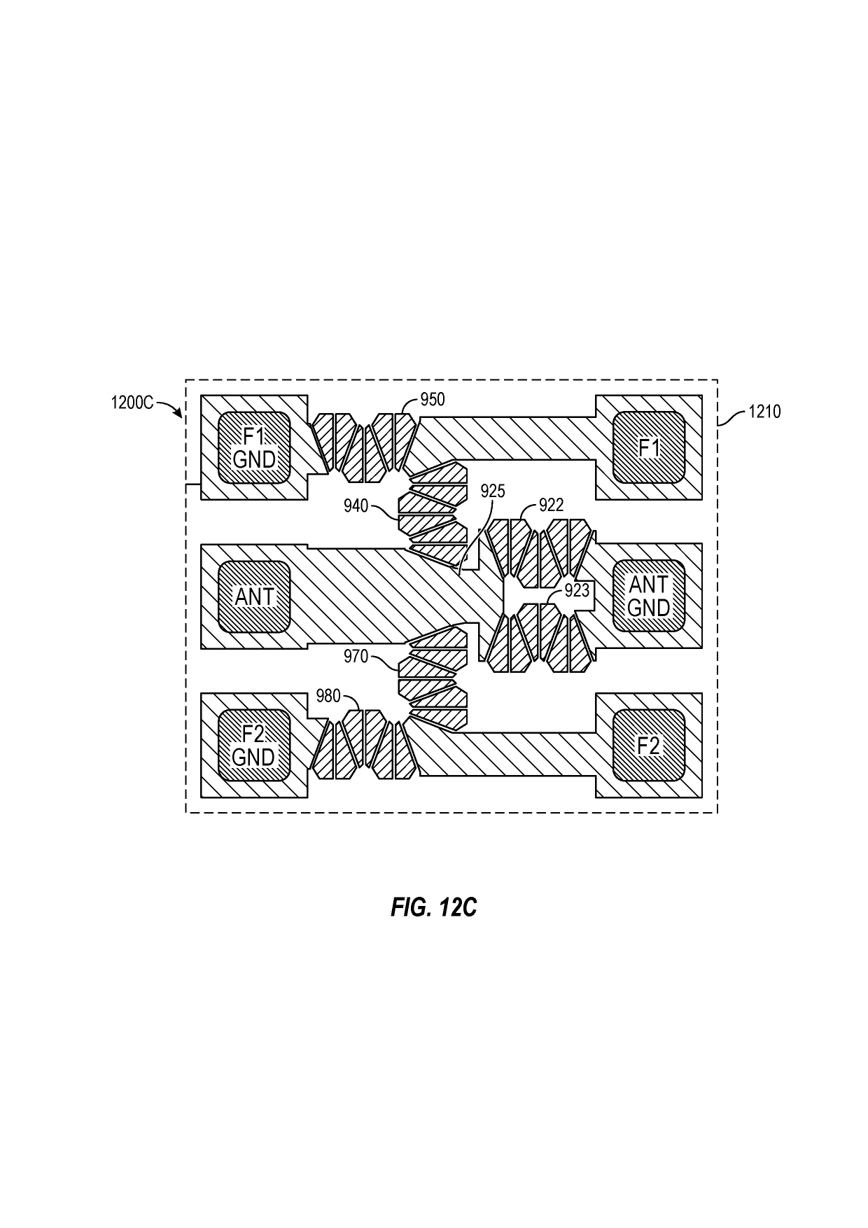

Referring to FIG. 12A, the dual-band filtenna 1200A may be similar to the dual-band filtenna 1100A and may thus include the antenna 910, the acoustic resonators 922, 923, the first filter branch 930, the second filter branch 960, a remaining portion of the first filter via port F1, and a remaining portion of the second filter via port F2. The dual-band filtenna 1200A, however, may additionally include one or more matching elements 926 (represented by matching node 2e) coupled to the antenna 910, to the acoustic resonators 922, 923, to the first filter branch 930, and to the second filter branch 960 at the common node 925. The one or more matching elements 926 may be passive elements, for example. The matching element(s) 926 may provide impedance matching in the dual-band filtenna 1200A and may allow for an easier physical realization of the desired dual-band filter performance. In some cases, the one or more matching elements 926 may be located off the acoustic die (e.g., on a substrate disposed below the acoustic die). As a result of the introduction of the one or more matching elements 926, the static capacitance of the acoustic resonators (e.g., acoustic resonators 922, 923, 940, 950, 970, 990) in the dual-band filtenna 1200A may be increased.

Referring to FIG. 12B, the dual-band filtenna 1200B may be similar to the dual-band filtenna 1100B, and may thus include the antenna 910, the at least one acoustic resonator 920 (implemented with acoustic resonators 922 and 923), the first filter branch 930, the second filter branch 960, a remaining portion of the first filter via port F1, and a remaining portion of the second filter via port F2. The dual-band filtenna 1200B, however, may additionally include the matching element(s) 926 coupled to the antenna 910, to the at least one acoustic resonator 920, to the first filter branch 930, and to the second filter branch 960 at the common node 925. In some cases, the one or more matching elements 926 may include an inductive element L9 coupled in shunt between the common node 925 and the ANT GND node (as illustrated), whereas in other cases, the one or more matching elements 926 may include a combination of an inductive element coupled in series with a capacitive element, the combination being coupled in shunt between the common node 925 and the ANT GND node (not illustrated).

The dual-band filtenna 1200C of FIG. 12C may be an example acoustic chip layout of the dual-band filtenna 1200A/1200B of FIG. 12A/12B. As depicted in FIG. 12C, the acoustic resonators 922, 923, the first filter branch 930 (including acoustic resonators 940 and 950 and the F1 GND node), the second filter branch 960 (including acoustic resonators 970 and 980 and the F2 GND node) may be disposed on a single acoustic die 1210, as illustrated. The matching element(s) 926 may be realized within a laminate (not shown), rather than on the acoustic die 1210. Thus, the example acoustic chip layout of the dual-band filtenna 1200C in FIG. 12C may be quite similar to the acoustic chip layout of the dual-band filtenna 1100C in FIG. 11C. For other aspects, the dual-band filtenna with dual shunt resonators and matching element(s) may be implemented on multiple acoustic dies, similar to the example acoustic chip layout in the dual-band filtenna 1100D of FIG. 11D.

According to certain aspects, the first filter branch 930 may be configured in combination with the antenna 910 and the at least one acoustic resonator 920 to have a first operating frequency band, and the second filter branch 960 may be configured in combination with the antenna 910 and the at least one acoustic resonator 920 to have a second operating frequency band, providing the dual bands of the dual-band filtennas 1000A-C, 1100A-D, and 1200A-C.

### Example Tri-Band Filtenna with Micro-Acoustic Resonators

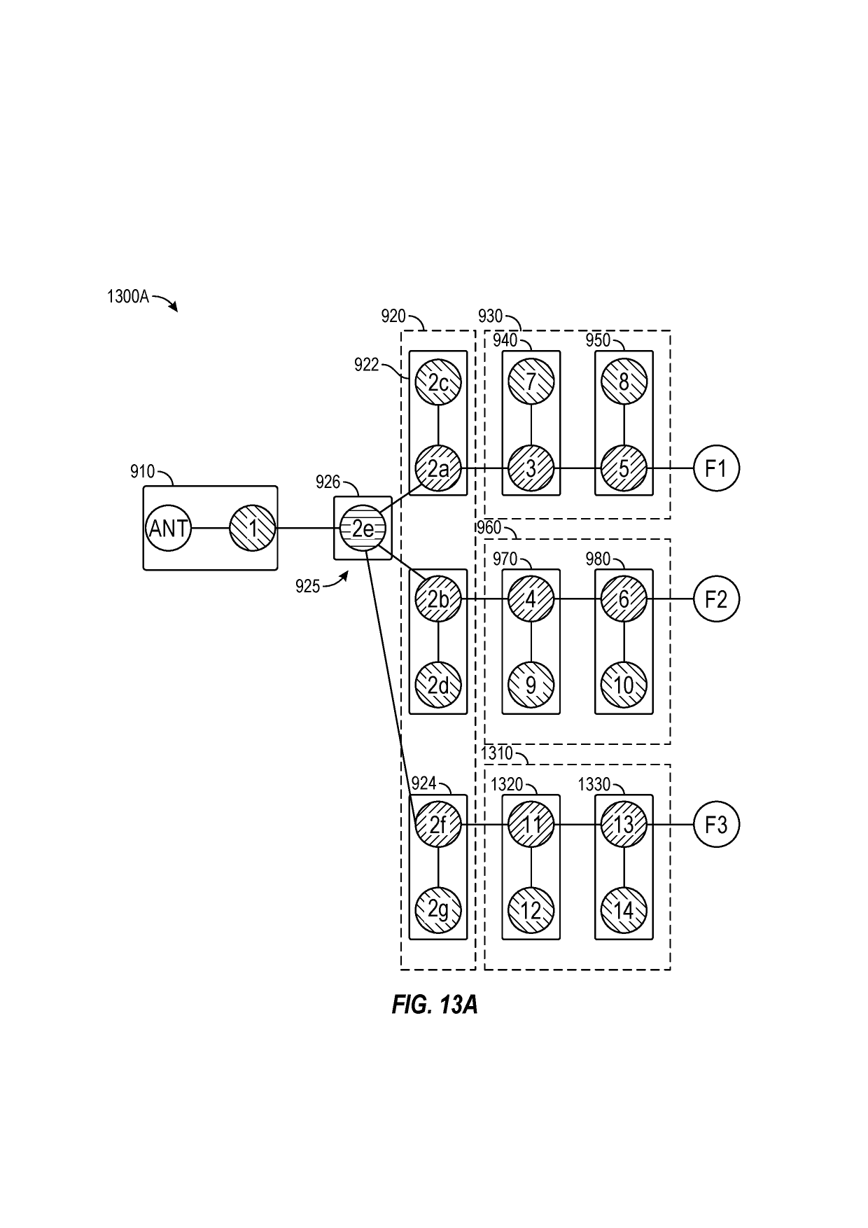

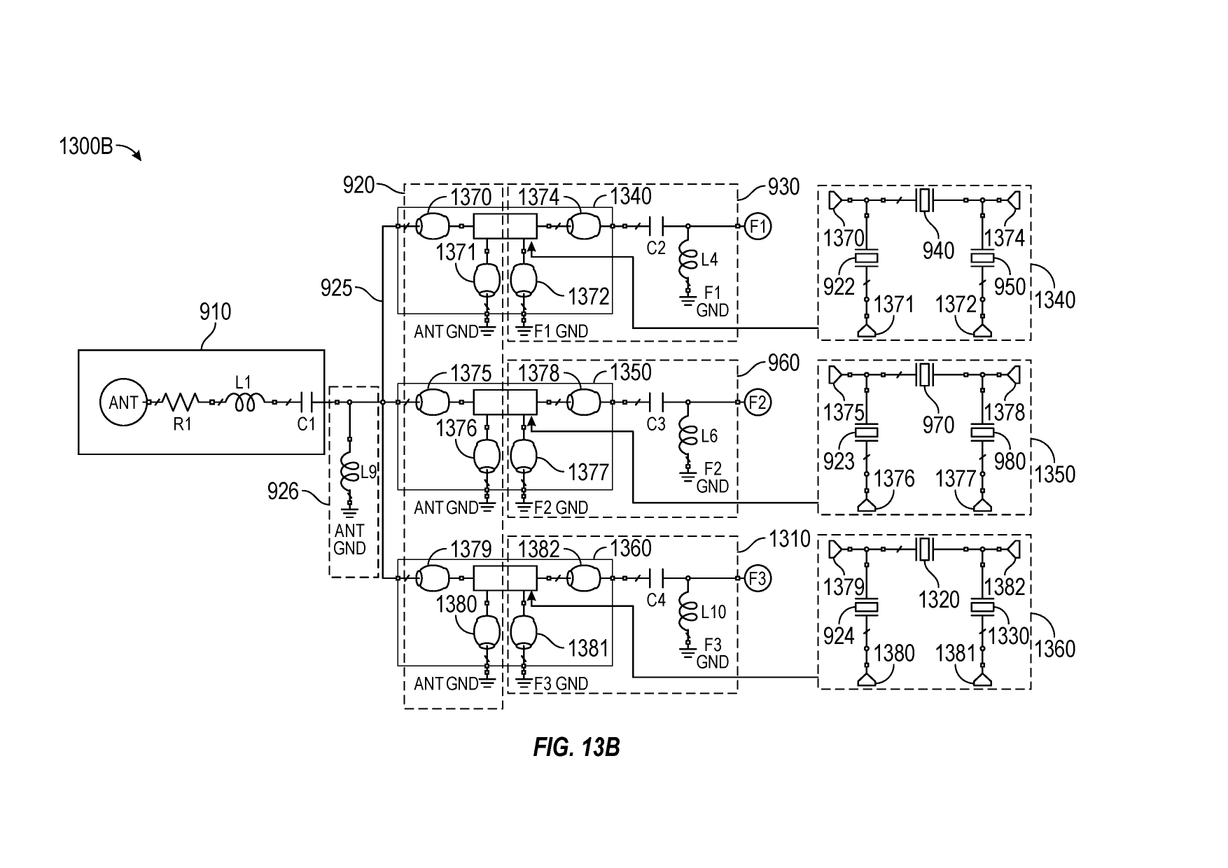

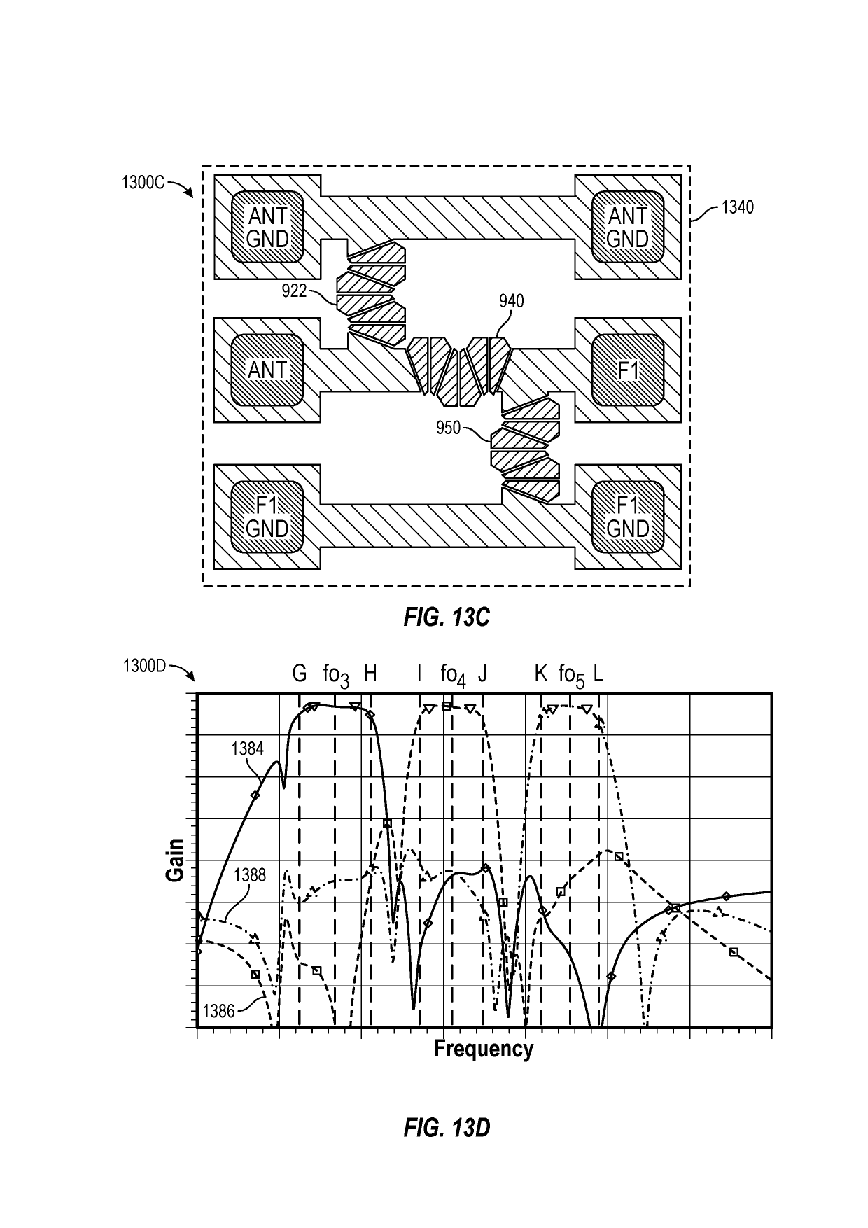

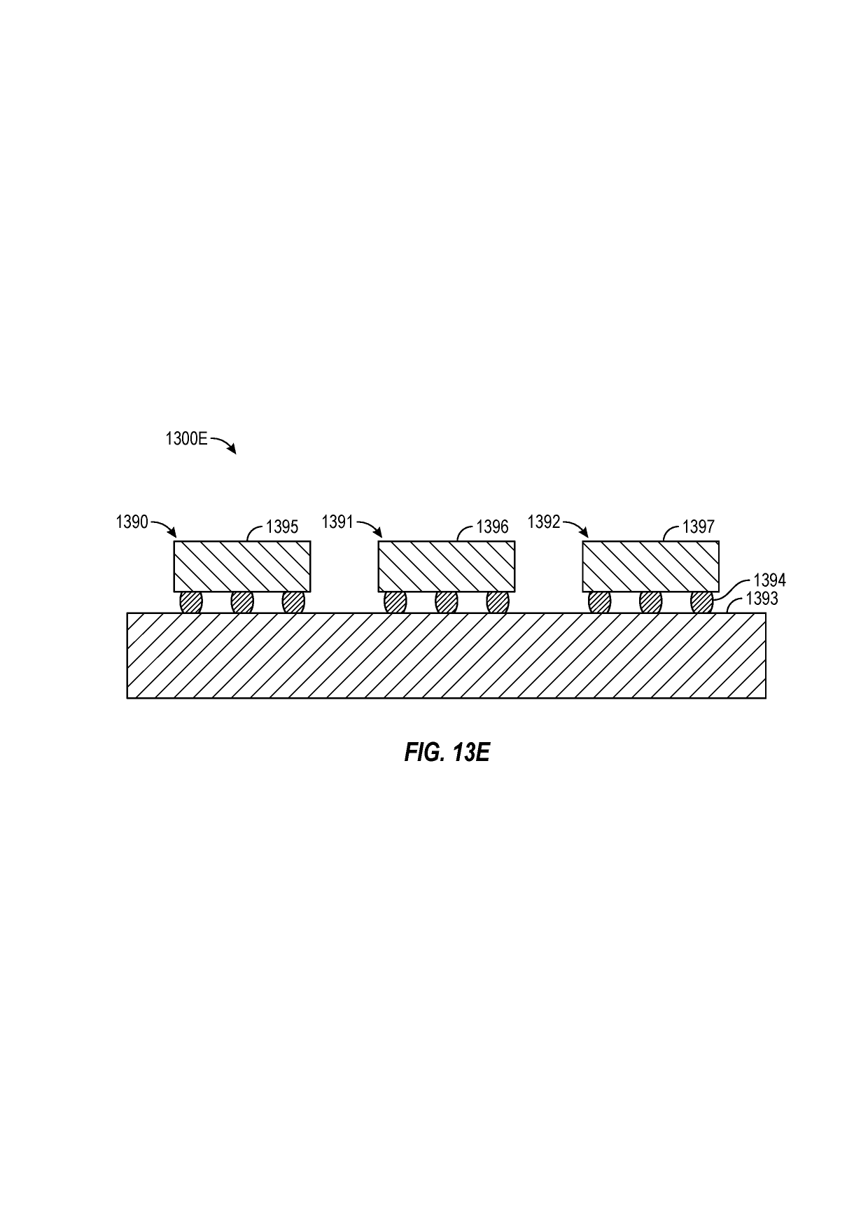

According to certain aspects of the present disclosure, the filtenna described herein may be expanded to more than two bands (e.g., a tri-band filtenna to with three frequency passbands), to provide even more versatility. FIG. 13A is a block diagram depicting an example tri-band filtenna 1300A, in accordance with certain aspects of the present disclosure. The tri-band filtenna 1300A may be similar to the dual-band filtenna 1200A, for example, and may include the antenna 910, the first filter branch 930, the second filter branch 960, a remaining portion of the first filter via port F1, a remaining portion of the second filter via port F2, and optionally the one or more matching elements 926. The tri-band filtenna 1300A, however, may additionally include a third filter branch 1310, and the at least one acoustic resonator 920 may additionally include an acoustic resonator 924 (including non-resonant node 2f and resonant node 2g), in addition to the acoustic resonator 922 and the acoustic resonator 923. The third filter branch 1310 may be coupled to the at least one acoustic resonator 920, as illustrated. The third filter branch 1310 may include an acoustic resonator 1320 (e.g., having series resonance), which includes a non-resonant node 11 and a resonant node 12, and an acoustic resonator 1330 (e.g., having parallel resonance) which includes a non-resonant node 13 and a resonant node 14. The antenna 910, the optional matching element(s) 926, the acoustic resonator 924, and the third filter branch 1310 may form at least a portion of a third filter of the tri-band filtenna 1300A. The third filter branch 1310 may be coupled to a remaining portion of the third filter via a third port (labeled “F3”). The at least one acoustic resonator 920 (and the optional matching element(s) 926) may be coupled to the antenna 910, the first filter branch 930, the second filter branch 960, and the third filter branch 1310 at the common node 925.

FIG. 13B is a schematic diagram of an example tri-band filtenna 1300B, in accordance with certain aspects of the present disclosure. The tri-band filtenna 1300B may be a schematic representation of the block diagram of tri-band filtenna 1300A.

The tri-band filtenna 1300B may include the antenna 910, the at least one acoustic resonator 920, the first filter branch 930, the second filter branch 960, and the third filter branch 1310. The at least one acoustic resonator 920 may be implemented with the acoustic resonator 922 (e.g., having parallel resonance), the acoustic resonator 923 (e.g., having parallel resonance), and the acoustic resonator 924 (e.g., having parallel resonance) coupled to the antenna 910, to the first filter branch 930, to the second filter branch 960, and to the third filter branch 1310 at the common node 925. The acoustic resonator 922 may be coupled in shunt between the common node 925 (e.g., via a port 1370, such as a solder bump, represented by a ferrite bead symbol) and the ANT GND node (e.g., via a port 1371), the acoustic resonator 923 may be coupled in shunt between the common node 925 (e.g., via a port 1375) and the ANT GND node (e.g., via a port 1376), and the acoustic resonator 924 may be coupled in shunt between the common node 925 (e.g., via a port 1379) and the ANT GND node (e.g., via a port 1380).

The tri-band filtenna 1300B may optionally additionally include one or more matching elements 926 coupled to the antenna 910, to the at least one acoustic resonator 920, to the first filter branch 930, to the second filter branch 960, and to the third filter branch 1310 at the common node 925. The one or more matching elements 926 (e.g., inductive element L9, as shown) may be coupled in shunt between the common node 925 and the ANT GND node.

The acoustic resonator 940 of the first filter branch 930 may be coupled in series to the common node 925 (e.g., via the port 1370), and the acoustic resonator 950 of the first filter branch 930 may be coupled in shunt between the acoustic resonator 940 and the F1 GND node (e.g., via a port 1372), as illustrated. The first filter branch 930 may also include a capacitive element C2 coupled in series with the acoustic resonator 940 (e.g., via a port 1374) and an inductive element L4 coupled in shunt between the capacitive element C2 and the F1 GND node, as illustrated. The first filter branch 930 may also be coupled to a remaining portion of the first filter via port F1.

The acoustic resonator 970 of the second filter branch 960 may be coupled in series to the common node 925 (e.g., via a port 1375), and the acoustic resonator 980 of the second filter branch 960 may be coupled in shunt between the acoustic resonator 970 and the F2 GND (e.g., via a port 1377), as illustrated. The second filter branch 960 may also include a capacitive element C3 coupled in series with the acoustic resonator 970 (e.g., via a port 1378) and an inductive element L6 coupled in shunt between the capacitive element C3 and the F2 GND node, as illustrated. The second filter branch 960 may also be coupled to a remaining portion of the second filter via port F2.

The acoustic resonator 1320 of the third filter branch 1310 may be coupled in series to the common node 925 (e.g., via a port 1379), and the acoustic resonator 1330 of the third filter branch 1310 may be coupled in shunt between the acoustic resonator 1320 and a fourth reference potential node (e.g., fourth electrical ground, labeled “F3 GND,” via a port 1381), as illustrated. The third filter branch 1310 may also include a capacitive element C4 coupled in series with the acoustic resonator 1320 (e.g., via a port 1382) and an inductive element L10 coupled in shunt between the capacitive element C4 and the F3 GND node, as illustrated. The third filter branch 1310 may also be coupled to a remaining portion of the third filter via port F2.

In certain aspects, the ANT GND node, the F1 GND node, the F2 GND node, and the F3 GND node are different nodes (e.g., separate grounds), for example, to help avoid cross-coupling. It is to be understood that the solder bumps (e.g., implementing ports 1370-1382) described herein may also be implemented by other interconnections (e.g., balls, pads, or the like).

In certain aspects, and as illustrated in FIG. 13C, the acoustic resonators 922, 940, and 950 may be disposed together on a first acoustic chip 1340, the acoustic resonators 923, 970, and 980 may be disposed together on a second acoustic chip 1350, and the acoustic resonators 924, 1320, and 1330 may be disposed together on a third acoustic chip 1360. In this manner, an individual acoustic chip may be used for each filter, and a wider range of passband frequencies may be used in the tri-band filtenna 1300B.

FIG. 13C is a top view of an example acoustic chip layout depicting a portion of an example tri-band filtenna 1300C, in accordance with certain aspects of the present disclosure. The portion of the tri-band filtenna 1300C may depict a top view of the acoustic chip layout of the first acoustic chip 1340 of the tri-band filtenna 1300B. As illustrated, the acoustic resonators 922, 940, 950 may be disposed together on the first acoustic chip 1340, as illustrated. As described above, the acoustic resonator 940 may be coupled between the one or more antenna elements ANT and the port F1. The acoustic resonator 950 may be coupled between the antenna element(s) ANT and the F1 GND node, and the acoustic resonator 922 may be coupled between the port F1 and the ANT GND node.

According to certain aspects, the first filter branch 930 may be configured in combination with the antenna 910 and the at least one acoustic resonator 920 to have a first operating frequency band, the second filter branch 960 may be configured in combination with the antenna 910 and the at least one acoustic resonator 920 to have a second operating frequency band, and the third filter branch 1310 may be configured in combination with the antenna 910 and the at least one acoustic resonator 920 to have a third operating frequency band, providing the three bands of the tri-band filtennas 1300A-C. It is to be understood that the filtenna described herein may be expanded to cover more than three frequency bands, and may be implemented as a multiband filtenna with any number of bands.

FIG. 13D is a frequency spectrum 1300D illustrating a distribution of example frequency responses and resonance frequencies associated with a tri-band filtenna, in accordance with certain aspects of the present disclosure. The spectrum 1300D illustrates a first passband of a frequency response 1384 of a first filter branch of a tri-band filtenna (e.g., a first filter transfer function of the tri-band filtenna, illustrating gain over frequency). The frequency response 1384 may be a combination of an admittance of an antenna, an admittance of at least one acoustic resonator (e.g., the acoustic resonator 922 in shunt), an admittance of one or more acoustic resonators in shunt in the first filter branch, and an admittance of one or more acoustic resonators in series in the first filter branch. The first passband may be characterized by a first center frequency (e.g., labeled “f0₃”) and a first bandwidth (e.g., the range from frequency G to frequency H).

The spectrum 1300D also illustrates a second passband of a frequency response 1386 of a second filter branch of the tri-band filtenna (e.g., a second filter transfer function of the tri-band filtenna, illustrating gain over frequency). The frequency response 1386 may be a combination of an admittance of the antenna, an admittance of at least one acoustic resonator (e.g., the acoustic resonator 923 in shunt), an admittance of one or more acoustic resonators in shunt in the second filter branch, and/or an admittance of one or more acoustic resonators in series in the second filter branch. The second passband may be characterized by a second center frequency (e.g., labeled “f0₄”) and a second bandwidth (e.g., the range from frequency I to frequency J).

The spectrum 1300D also illustrates a third passband of a frequency response 1388 of a third filter branch of the tri-band filtenna (e.g., a third filter transfer function of the tri-band filtenna, illustrating gain over frequency). The frequency response 1388 may be a combination of an admittance of the antenna, an admittance of at least one acoustic resonator (e.g., the acoustic resonator 924 in shunt), an admittance of one or more acoustic resonators in shunt in the third filter branch, and/or an admittance of one or more acoustic resonators in series in the third filter branch. The third passband may be characterized by a third center frequency (e.g., labeled “f0₅”) and a third bandwidth (e.g., the range from frequency K to frequency L). As an example, the first passband may range from 16.5 GHz to 17 GHz, the second passband may range from 17.8 GHz to 18.3 GHz, and the third passband may range from 19.3 GHz to 19.7 GHz.

In some cases, it may be challenging to implement a multiband filtenna using a singular chip, especially if the series resonances of the acoustic resonators in the multiband filtenna are drastically different. As such, it may be beneficial to implement a multiband filtenna on multiple acoustic dies. FIG. 13E is a cross-sectional view of an example module 1300E for a tri-band filtenna that includes filtenna submodules 1390, 1391, and 1392 (e.g., each being similar to filtenna submodule 610a) disposed above a substrate 1393 (e.g., a substrate similar to substrate 650 and/or metal layer 660), in accordance with certain aspects of the present disclosure. The substrate 1393 may include or be implemented by, for example, a laminate that includes passive components such as inductors and/or capacitors (e.g., integrated or lumped inductors and/or capacitors).

The filtenna submodules 1390, 1391, and 1392 may include acoustic dies 1395, 1396, 1397, respectively. In certain aspects, the dies 1395, 1396, and 1397 may be coupled to one or more solder balls 1394 or other suitable electrically conductive structures to mechanically attach and electrically couple the dies 1395, 1396, and 1397 to the substrate 1393 and form the module 1300E. In some aspects, the dies 1395, 1396, and 1397 may be disposed adjacent to a radiating element (e.g., an antenna similar to antenna 620 in FIGS. 6A and 6B) above the substrate 1393. This radiating element may be located behind or in front of the dies and is thus not shown in the particular cross-sectional view of FIG. 13E. In this manner, a multiband filtenna (which includes the filtenna submodules 1390, 1391, and 1392) may be realized using multiple chips. In some cases, the substrate 1393 may be disposed above a printed circuit board (PCB) (e.g., a PCB similar to PCB 680 in FIGS. 6A and 6B), and the substrate 1393 may be mechanically attached and electrically coupled to the PCB via one or more additional solder balls (not illustrated).

### Example Multiband Filtenna Operations

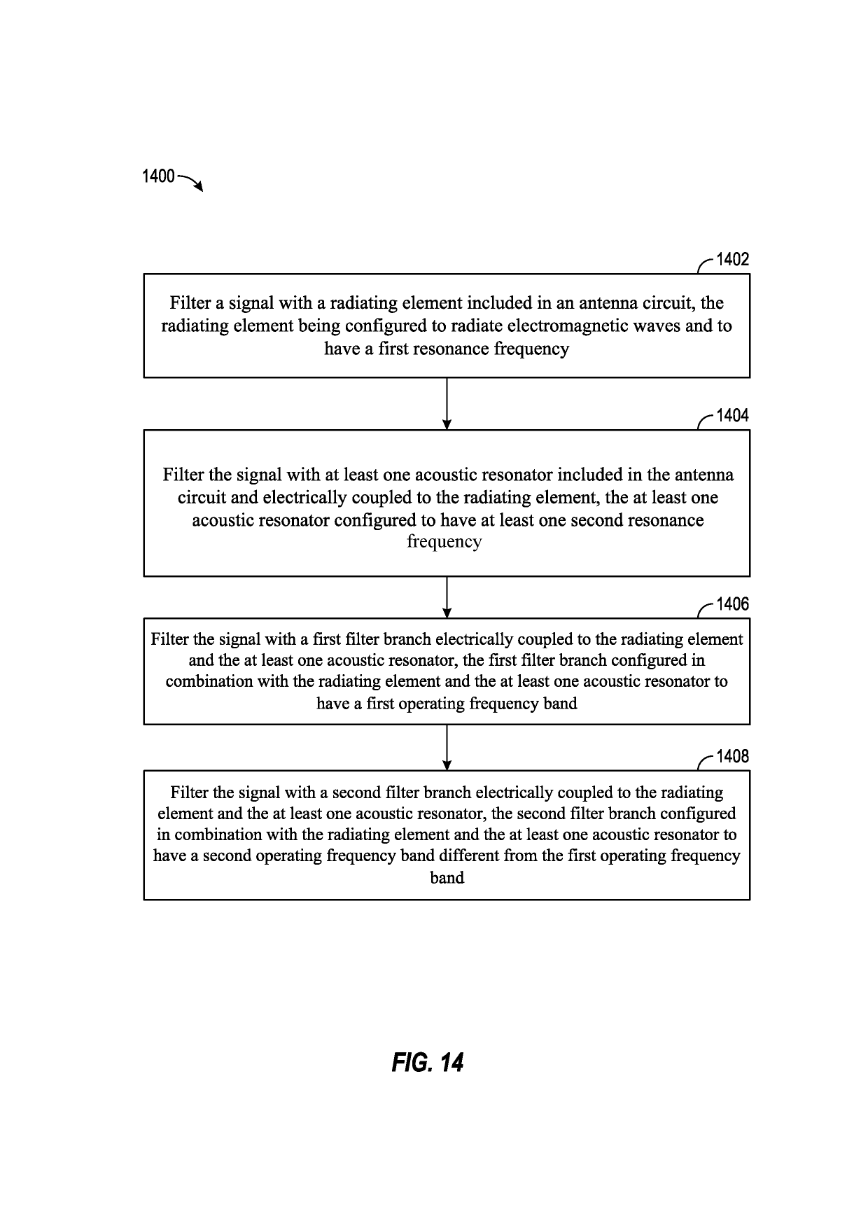

FIG. 14 is a flow diagram of example operations 1400 for processing a signal using an antenna circuit (e.g., dual-band filtenna 1000A, 1000B, 1000C, 1100A, 1100B, 1100C, 1100D, 1200A, 1200B, 1200C of FIGS. 10A-C, 11A-D, and 12A-C, or tri-band filtenna 1300A, 1300B, 1300C, of FIGS. 13A-C), in accordance, with certain aspects of the present disclosure.

The operations 1400 may include, at block 1402, filtering the signal with a radiating element (e.g., antenna 910) included in the antenna circuit. The radiating element may be configured to radiate electromagnetic waves and to have a first resonance frequency.

At block 1404, the operations 1400 may include filtering the signal with at least one acoustic resonator (e.g., acoustic resonator 920) included in the antenna circuit and electrically coupled to the radiating element. The at least one acoustic resonator may be configured to have at least one second resonance frequency. The antenna circuit may be configured to have a filter transfer function based at least in part on the first resonance frequency and the second resonance frequency.

At block 1406, the operations 1400 may include filtering the signal with a first filter branch (e.g., first filter branch 930) electrically coupled to the radiating element and the at least one acoustic resonator. The first filter branch may be configured in combination with the radiating element and the at least one acoustic resonator to have a first operating frequency band.

At block 1408, the operations 1400 may include filtering the signal with a second filter branch (e.g., second filter branch 960) electrically coupled to the radiating element and the at least one acoustic resonator. The second filter branch may be configured in combination with the radiating element and the at least one acoustic resonator to have a second operating frequency band different from the first operating frequency band.

### Example Applications of a Filtenna

FIG. 15 illustrates a schematic diagram of an example filtenna circuit 1500 using micro-acoustic resonators, in accordance with certain aspects of the present disclosure. The filtenna circuit 1500 includes an antenna 1502—for example, including a radiating element (functioning as an input or output terminal for the circuit, as well as a resonator of the filtenna circuit)—and a terminal 1514 (which may function as an output or input terminal, respectively, for the circuit). Between the antenna 1502 and the terminal 1514, a ladder-type network of acoustic resonators is provided. The acoustic resonators may be implemented by any of various suitable devices, such as BAW resonators (including solidly mounted resonator (SMR)-type BAW resonators), SAW resonators, thin-film bulk acoustic resonators (FBARs), micro-electromechanical systems (MEMS) devices, or any combination thereof. The filtenna circuit 1500 includes a first acoustic resonator 1504, a second acoustic resonator 1506, a third acoustic resonator 1508, and a fourth acoustic resonator 1509, all electrically connected in a series path between the antenna 1502 and the terminal 1514. A fifth acoustic resonator 1510 (e.g., a shunt resonator) has a first terminal connected to a node between the first acoustic resonator 1504 and the second acoustic resonator 1506 and has a second terminal connected to a reference potential node 1530 (e.g., electric ground) for the filtenna circuit 1500. A sixth acoustic resonator 1512 (e.g., a shunt resonator) has a first terminal connected to a node between the second acoustic resonator 1506 and the third acoustic resonator 1508 and has a second terminal connected to the reference potential node 1530. A seventh acoustic resonator 1513 (e.g., a shunt resonator) has a first terminal connected to a node between the third acoustic resonator 1508 and the fourth acoustic resonator 1509 and has a second terminal connected to the reference potential node 1530. Although not shown, any of the acoustic resonators in the filtenna circuit 1500 may be coupled in series or in parallel with additional passive elements, such as one or more inductors and/or one or more capacitors.

FIG. 1600 is a functional block diagram of at least a portion of an example of a simplified wireless transceiver circuit 1600 in which a multiband filtenna (e.g., dual-band filtenna 1000A, 1000B, 1000C, 1100A, 1100B, 1100C, 1100D, 1200A, 1200B, 1200C of FIGS. 10A-C, 11A-D, and 12A-C, or tri-band filtenna 1300A, 1300B, 1300C, of FIGS. 13A-C) or filtenna circuit (e.g., the filtenna circuit 1500 of FIG. 15) may be employed. The transceiver circuit 1600 is configured to receive signals/information for transmission (shown as in-phase (I) and quadrature (Q) values) which is provided to one or more baseband (BB) filters 1612. The filtered output is provided to one or more mixers 1614 for upconversion to radio frequency (RF) signals. The output from the one or more mixers 1614 may be provided to a driver amplifier (DA) 1616 whose output may be provided to a power amplifier (PA) 1618 to produce an amplified signal for wireless transmission. The amplified signal may be output to the antenna 1622 through one or more filters including a filtenna 1620 (of which the antenna 1622 is a part). The filtenna 1620 may be implemented by any suitable filtenna or filtenna circuit.

The antenna 1622 may be used for both wirelessly transmitting and receiving signals (e.g., using a transmit/receive (T/R) switch (not shown) for time-division duplexing (TDD)). The transceiver circuit 1600 includes a receive path through the one or more filters (e.g., through the filtenna 1620) to be provided to a LNA 1624 and a further filter 1626 and then downconverted from the receive frequency to a baseband frequency through one or more mixer circuits 1628 before the signal is further processed (e.g., provided to an analog-to-digital converter (ADC) and then demodulated or otherwise processed in the digital domain). There may be separate filters for the receive circuit (e.g., the receive circuit may have a separate antenna or have separate receive filters) that may be implemented using any suitable filtenna or filtenna circuit.

FIG. 17 is a diagram of an environment 1700 that includes an electronic device 1702, in which aspects of the present disclosure may be practiced. In the environment 1700, the electronic device 1702 communicates with a base station 1704 (or other network node) through a wireless link 1706. As shown, the electronic device 1702 is depicted as a smartphone. However, the electronic device 1702 may be implemented as any suitable computing or other electronic device, such as a cellular base station, broadband router, access point, cellular or mobile phone, gaming device, navigation device, media device, laptop computer, desktop computer, tablet computer, server computer, network-attached storage (NAS) device, smart appliance, vehicle-based communication system, Internet of Things (IoT) device, sensor or security device, asset tracker, extended reality device, wearable device, and so forth.

The base station 1704 communicates with the electronic device 1702 via the wireless link 1706, which may be implemented as any suitable type of wireless link. Although depicted as a base station tower of a cellular radio network, the base station 1704 may represent or be implemented as another device, such as a satellite, terrestrial broadcast tower, access point, peer-to-peer device, mesh network node, fiber optic line, another electronic device generally as described above, and so forth. Hence, the electronic device 1702 may communicate with the base station 1704 or another device via a wired connection, a wireless connection, or a combination thereof. The wireless link 1706 can include a downlink of data or control information communicated from the base station 1704 to the electronic device 1702 and an uplink of other data or control information communicated from the electronic device 1702 to the base station 1704. The wireless link 1706 may be implemented using any suitable communication protocol or standard, such as 3rd Generation Partnership Project (3GPP) Long-Term Evolution (LTE), 3GPP New Radio (NR) 5G, Institute of Electrical and Electronics Engineers (IEEE) 802.11, IEEE 802.15, IEEE 802.16, Bluetooth™, and so forth.

The electronic device 1702 includes at least one processor 1780 and at least one memory 1782. The memory 1782 may be or form a portion of a computer-readable storage medium. The processor 1780 may include any type of processor, such as an application processor or a multi-core processor, that is configured to execute processor-executable instructions (e.g., code) stored by the memory 1782. The memory 1782 may include any suitable type of data storage media, such as volatile memory (e.g., random access memory (RAM)), non-volatile memory (e.g., flash memory), optical media, magnetic media (e.g., disk or tape), and so forth. In the context of this disclosure, the memory 1782 is implemented to store instructions 1784, data 1786, and other information of the electronic device 1702, and thus when configured as or part of a computer-readable storage medium, the memory 1782 does not include transitory propagating signals or carrier waves.

The electronic device 1702 may also include input/output ports 1790. The I/O ports 1790 enable data exchanges or interaction with other devices, networks, or users or between components of the device.

The electronic device 1702 may further include at least one signal processor 1792 (e.g., such as a digital signal processor (DSP)). The signal processor 1792 may function similar to the processor and may be capable of executing instructions and/or processing information in conjunction with the memory 1782.

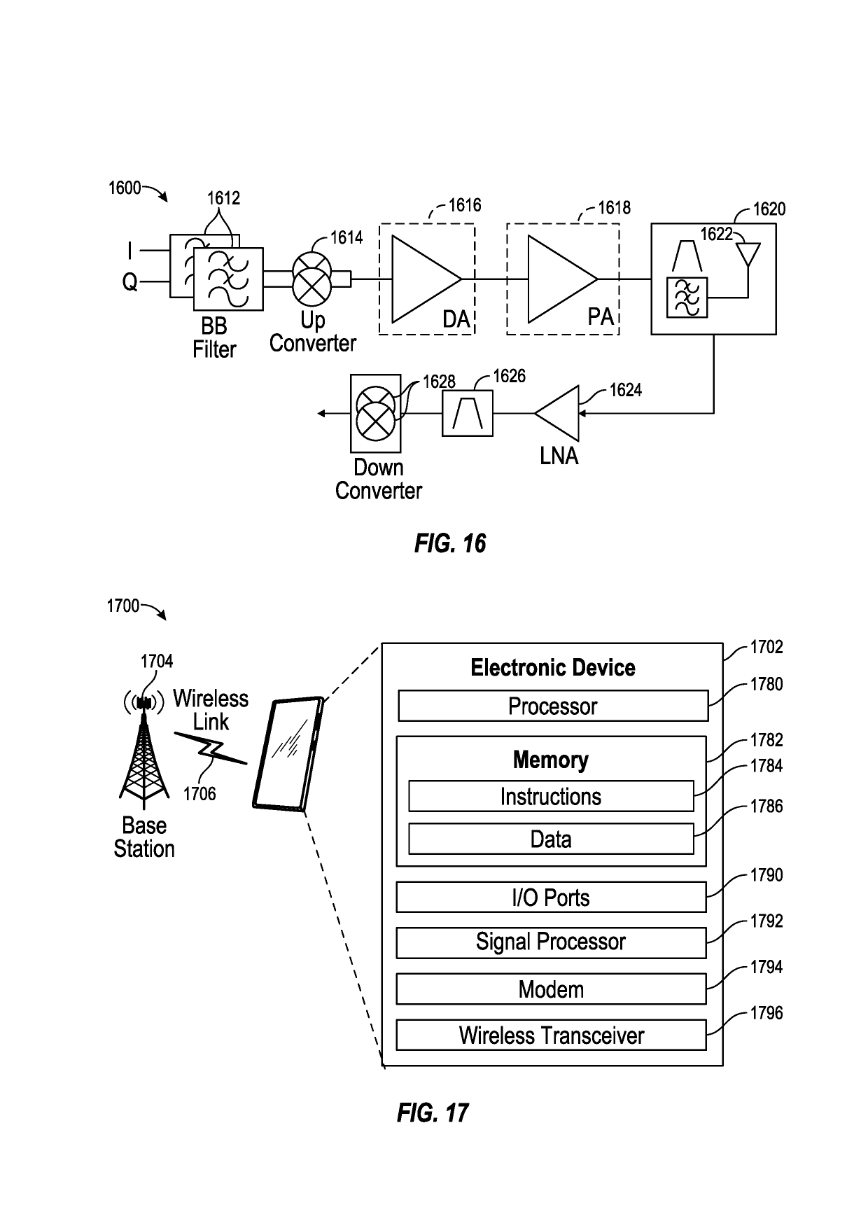

For communication purposes, the electronic device 1702 also includes a modem 1794, a wireless transceiver 1796, and an antenna (not shown) as part of a filtenna. The wireless transceiver 1796 provides connectivity to respective networks and other electronic devices connected therewith using RF wireless signals and may include the transceiver circuit 1600 of FIG. 16. The wireless transceiver 1796 may facilitate communication over any suitable type of wireless network, such as a wireless local area network (WLAN), a peer-to-peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN) (e.g., using ultra-wideband (UWB) technology).

### Example Aspects

In addition to the various aspects described above, specific combinations of aspects are within the scope of the disclosure, some of which are detailed below:

Aspect 1: An apparatus comprising: an antenna circuit comprising: a radiating element configured to radiate electromagnetic waves and to have a first resonance frequency; at least one acoustic resonator electrically coupled to the radiating element and configured to have at least one second resonance frequency; a first filter branch electrically coupled to the radiating element and the at least one acoustic resonator and configured in combination with the radiating element and the at least one acoustic resonator to have a first operating frequency band; and a second filter branch electrically coupled to the radiating element and the at least one acoustic resonator and configured in combination with the radiating element and the at least one acoustic resonator to have a second operating frequency band different from the first operating frequency band.

Aspect 2: The apparatus of Aspect 1, wherein the at least one acoustic resonator is a single acoustic resonator coupled to the radiating element, to the first filter branch, and to the second filter branch at a common node.

Aspect 3: The apparatus of Aspect 2, wherein the first resonance frequency of the radiating element is a series resonance frequency and wherein the single acoustic resonator is disposed adjacent to the radiating element and is coupled in shunt with the radiating element.

Aspect 4: The apparatus of Aspect 2 or 3, wherein: the single acoustic resonator is coupled between the common node and a first reference potential node; the first filter branch comprises a first acoustic resonator coupled between the common node and a first filter node and a second acoustic resonator coupled between the first filter node and a second reference potential node; the second filter branch comprises a third acoustic resonator coupled between the common node and a second filter node and a fourth acoustic resonator coupled between the second filter node and a third reference potential node; and the first reference potential node, the second reference potential node, and the third reference potential node are different nodes.

Aspect 5: The apparatus of Aspect 4, wherein the first reference potential node is a reference potential node associated with the radiating element.

Aspect 6: The apparatus of Aspect 4, wherein the first reference potential node, the second reference potential node, and the third reference potential node are physically separated from each other on a die.

Aspect 7: The apparatus of Aspect 1, wherein the at least one acoustic resonator comprises a first acoustic resonator and a second acoustic resonator, the first and second acoustic resonators being coupled to the radiating element, to the first filter branch, and to the second filter branch at a common node.

Aspect 8: The apparatus of Aspect 7, wherein a resonance frequency of the first acoustic resonator is different than a resonance frequency of the second acoustic resonator.

Aspect 9: The apparatus of Aspect 7 or 8, wherein the first acoustic resonator is coupled between the common node and a first reference potential node and wherein the second acoustic resonator is coupled between the common node and the first reference potential node.

Aspect 10: The apparatus of Aspect 9, wherein: the first filter branch comprises a third acoustic resonator coupled between the common node and a first filter node and a fourth acoustic resonator coupled between the first filter node and a second reference potential node; the second filter branch comprises a fifth acoustic resonator coupled between the common node and a second filter node and a sixth acoustic resonator coupled between the second filter node and a third reference potential node; and the first reference potential node, the second reference potential node, and the third reference potential node are different nodes.

Aspect 11: The apparatus of Aspect 10, wherein the first reference potential node is a reference potential node associated with the radiating element.

Aspect 12: The apparatus according to any of Aspects 7–11, wherein the antenna circuit further comprises one or more passive elements coupled to the radiating element, to the at least one acoustic resonator, to the first filter branch, and to the second filter branch at the common node.

Aspect 13: The apparatus of Aspect 12, wherein the one or more passive elements comprise: an inductive element coupled in shunt with the radiating element; or a combination of the inductive element coupled in series with a capacitive element, the combination being coupled in shunt with the radiating element.

Aspect 14: The apparatus according to any of Aspects 7–13, wherein the first acoustic resonator and at least a portion of the first filter branch are disposed on a first die and wherein the second acoustic resonator and at least a portion of the second filter branch are disposed on a second die different from the first die.

Aspect 15: The apparatus according to any of Aspects 1–14, wherein the at least one acoustic resonator, the first filter branch, and the second filter branch are disposed on a single die.

Aspect 16: The apparatus according to any of Aspects 1–15, further comprising a third filter branch electrically coupled to the radiating element and the at least one acoustic resonator and configured in combination with the radiating element and the at least one acoustic resonator to have a third operating frequency band different from the first operating frequency band and the second operating frequency band.

Aspect 17: The apparatus according to any of Aspects 1–16, wherein the radiating element and the at least one acoustic resonator are co-located together such that a conductive line coupling the radiating element to the at least one acoustic resonator forms a portion of the radiating element.

Aspect 18: The apparatus according to any of Aspects 1–17, wherein at least one of the first filter branch or the second filter branch comprises a plurality of bulk acoustic wave (BAW) resonators coupled in a ladder-type configuration.

Aspect 19: The apparatus according to any of Aspects 1–18, wherein the at least one acoustic resonator is directly connected to a feedline of the radiating element without a transmission line coupled between the feedline and the at least one acoustic resonator.

Aspect 20: The apparatus according to any of Aspects 1–19, further comprising at least one of a transmitter or a receiver coupled to the antenna circuit, the transmitter being configured to transmit first wireless signals from the radiating element of the antenna circuit and the receiver being configured to receive second wireless signals with the radiating element of the antenna circuit.

Aspect 21: The apparatus according to any of Aspects 1–20, wherein the antenna circuit is configured to have a filter transfer function based at least in part on the first resonance frequency and the second resonance frequency

Aspect 22: The apparatus according to any of Aspects 1–21, wherein the apparatus is a packaged assembly.

Aspect 23: The apparatus of Aspect 21, wherein the packaged assembly further includes an active device coupled to the antenna circuit.

Aspect 24: A method of processing a signal using an antenna circuit, the method comprising: filtering the signal with a radiating element included in the antenna circuit, the radiating element being configured to radiate electromagnetic waves and to have a first resonance frequency; filtering the signal with at least one acoustic resonator included in the antenna circuit and electrically coupled to the radiating element, the at least one acoustic resonator being configured to have at least one second resonance frequency; filtering the signal with a first filter branch electrically coupled to the radiating element and the at least one acoustic resonator, the first filter branch being configured in combination with the radiating element and the at least one acoustic resonator to have a first operating frequency band; and filtering the signal with a second filter branch electrically coupled to the radiating element and the at least one acoustic resonator, the second filter branch being configured in combination with the radiating element and the at least one acoustic resonator to have a second operating frequency band different from the first operating frequency band.

Aspects 25: The method of Aspect 24, wherein the antenna circuit is configured to have a filter transfer function based at least in part on the first resonance frequency and the second resonance frequency.

### Additional Considerations

The various operations of methods described above may be performed by any suitable means capable of performing the corresponding functions. The means may include various hardware and/or software component(s) and/or module(s).

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuit.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes, and variations may be made in the arrangement, operation, and details of the methods and apparatus described above without departing from the scope of the claims.

1. An apparatus comprising:
an antenna circuit comprising:
a radiating element configured to radiate electromagnetic waves and to have a first resonance frequency;
at least one acoustic resonator electrically coupled to the radiating element and configured to have at least one second resonance frequency;
a first filter branch electrically coupled to the radiating element and the at least one acoustic resonator and configured in combination with the radiating element and the at least one acoustic resonator to have a first operating frequency band; and
a second filter branch electrically coupled to the radiating element and the at least one acoustic resonator and configured in combination with the radiating element and the at least one acoustic resonator to have a second operating frequency band different from the first operating frequency band.

2. The apparatus of claim 1, wherein the at least one acoustic resonator is a single acoustic resonator coupled to the radiating element, to the first filter branch, and to the second filter branch at a common node.

3. The apparatus of claim 2, wherein the first resonance frequency of the radiating element is a series resonance frequency and wherein the single acoustic resonator is disposed adjacent to the radiating element and is coupled in shunt with the radiating element.

4. The apparatus of claim 2, wherein:
the single acoustic resonator is coupled between the common node and a first reference potential node;
the first filter branch comprises a first acoustic resonator coupled between the common node and a first filter node and a second acoustic resonator coupled between the first filter node and a second reference potential node;
the second filter branch comprises a third acoustic resonator coupled between the common node and a second filter node and a fourth acoustic resonator coupled between the second filter node and a third reference potential node; and
the first reference potential node, the second reference potential node, and the third reference potential node are different nodes.

5. The apparatus of claim 4, wherein the first reference potential node is a reference potential node associated with the radiating element.

6. The apparatus of claim 4, wherein the first reference potential node, the second reference potential node, and the third reference potential node are physically separated from each other on a die.

7. The apparatus of claim 1, wherein the at least one acoustic resonator comprises a first acoustic resonator and a second acoustic resonator, the first and second acoustic resonators being coupled to the radiating element, to the first filter branch, and to the second filter branch at a common node.

8. The apparatus of claim 7, wherein a resonance frequency of the first acoustic resonator is different than a resonance frequency of the second acoustic resonator.

9. The apparatus of claim 7, wherein the first acoustic resonator is coupled between the common node and a first reference potential node and wherein the second acoustic resonator is coupled between the common node and the first reference potential node.

10. The apparatus of claim 9, wherein:
the first filter branch comprises a third acoustic resonator coupled between the common node and a first filter node and a fourth acoustic resonator coupled between the first filter node and a second reference potential node;
the second filter branch comprises a fifth acoustic resonator coupled between the common node and a second filter node and a sixth acoustic resonator coupled between the second filter node and a third reference potential node; and
the first reference potential node, the second reference potential node, and the third reference potential node are different nodes.

11. The apparatus of claim 10, wherein the first reference potential node is a reference potential node associated with the radiating element.

12. The apparatus of claim 7, wherein the antenna circuit further comprises one or more passive elements including an inductive element coupled to the radiating element, to the at least one acoustic resonator, to the first filter branch, and to the second filter branch at the common node.

13. The apparatus of claim 7, wherein the first acoustic resonator and at least a portion of the first filter branch are disposed on a first die and wherein the second acoustic resonator and at least a portion of the second filter branch are disposed on a second die different from the first die.

14. The apparatus of claim 1, wherein the at least one acoustic resonator, the first filter branch, and the second filter branch are disposed on a single die.

15. The apparatus of claim 1, further comprising a third filter branch electrically coupled to the radiating element and the at least one acoustic resonator and configured in combination with the radiating element and the at least one acoustic resonator to have a third operating frequency band different from the first operating frequency band and the second operating frequency band.

16. The apparatus of claim 1, wherein the radiating element and the at least one acoustic resonator are co-located together such that a conductive line coupling the radiating element to the at least one acoustic resonator forms a portion of the radiating element.

17. The apparatus of claim 1, wherein at least one of the first filter branch or the second filter branch comprises a plurality of bulk acoustic wave (BAW) resonators coupled in a ladder-type configuration.

18. The apparatus of claim 1, wherein the at least one acoustic resonator is directly connected to a feedline of the radiating element without a transmission line coupled between the feedline and the at least one acoustic resonator.

19. The apparatus of claim 1, further comprising at least one of a transmitter or a receiver coupled to the antenna circuit, the transmitter being configured to transmit first wireless signals from the radiating element of the antenna circuit and the receiver being configured to receive second wireless signals with the radiating element of the antenna circuit.

20. A method of processing a signal using an antenna circuit, the method comprising:
filtering the signal with a radiating element included in the antenna circuit, the radiating element being configured to radiate electromagnetic waves and to have a first resonance frequency;
filtering the signal with at least one acoustic resonator included in the antenna circuit and electrically coupled to the radiating element, the at least one acoustic resonator being configured to have at least one second resonance frequency;
filtering the signal with a first filter branch electrically coupled to the radiating element and the at least one acoustic resonator, the first filter branch being configured in combination with the radiating element and the at least one acoustic resonator to have a first operating frequency band; and
filtering the signal with a second filter branch electrically coupled to the radiating element and the at least one acoustic resonator, the second filter branch being configured in combination with the radiating element and the at least one acoustic resonator to have a second operating frequency band different from the first operating frequency band.
